(19) United States
(12) Patent Application Publication
(10) Pub. No.: US 2016/0226107 A1
(43) Pub. Date: Aug. 4, 2016

(54) METHOD AND SYSTEM FOR BATTERY MANAGEMENT

(71) Applicant: ELITE POWER INNOVATIONS, LLC, Sunnyvale, CA (US)

(72) Inventors: Michael Alan Worry, Campbell, CA (US); John Ellis Corman, Kitchener (CA); Stefan Erik Janhunen, Waterloo (CA); Donghyun Shin, Kitchener (CA); Jonathan Thomas Malton, Kitchener (CA); Nathanael Dimitro Wennyk, Waterloo (CA)

(73) Assignee: ELITE POWER INNOVATIONS, LLC

(21) Appl. No.: 14/836,895

(22) Filed: Aug. 26, 2015

Related U.S. Application Data
(60) Provisional application No. 62/042,156, filed on Aug. 26, 2014.
(60) Provisional application No. 62/050,282, filed on Sep. 15, 2014.

(51) Int. Cl. H01M 10/42; H01M 10/48; G01R 31/36

(52) U.S. Cl. CPC H01M 10/425; G01R 31/3658; H01M 10/4207; H01M 10/482; H01M 2010/4271; H01M 2010/4278

(57) ABSTRACT

A battery management system is provided that controls at least a stack of battery cells. The battery management system may detect stack voltage and current. Characteristics of each battery cell in the stack may be monitored. The battery management system may detect ground fault within the stack of battery cells. Communication breakdown and/or failure in the battery management system may also be detected.

### CROSS-REFERENCE TO RELATED APPLICATIONS

This application claims priority benefit of U.S. Provisional Patent Application No. 62/042,156 (current Docket #6326.01p, our Docket #CG-1), entitled “BATTERY MANAGEMENT SYSTEM,” filed on Aug. 26, 2014, by Michael Alan Worry, which is incorporated herein by reference; this application also claims priority benefit of U.S. Provisional Patent Application No. 62/050,282 (current Docket #6326.02p Docket #CG-2), entitled “MODULAR BATTERY MANAGEMENT,” filed on Sep. 15, 2014, by Michael Alan Worry, which is incorporated herein by reference.

### FIELD

The present specification relates to battery management.

### BACKGROUND

The subject matter discussed in the background section should not be assumed to be prior art merely as a result of its mention in the background section. Similarly, a problem mentioned in the background section or associated with the subject matter of the background section should not be assumed to have been previously recognized in the prior art. The subject matter in the background section merely represents different approaches, which in and of themselves may also be inventions.

Battery management is used to control one or more batteries. Common functions of battery management include charging and balancing batteries.

### SUMMARY

In at least one embodiment, a system and method for battery management is provided. In at least one embodiment, the battery management system is configured to monitor and control an energy storage system that includes a plurality of batteries, which may be charged, via a charger, and/or may output electrical power, via an inverter, to a power grid.

In at least one embodiment, the battery management system includes a means to monitor and manage at least a battery stack that includes a number of battery cells connected in series. The battery management system also includes a power interface that is configured to control switches in a power line that delivers current to and from the battery stack. In at least one embodiment, the power interface is configured to measure a voltage and/or a current on the power line. The battery management system may further include a plurality of cell interfaces, each of which is connected to a battery cell in the battery stack and is configured to measure characteristics of the connected battery cell. In at least one embodiment, the cell interfaces are configured to measure at least voltages and/or temperatures of the connected battery cells. Each of the cell interfaces is configured to communicate digital results of the measurements via a digital communications channel (e.g., a link bus) to a stack controller of the battery management system. The stack controller receives and/or analyzes the digital results and sends control signals to the power interface, via a stack bus. The power interface, based on the control signals received from the stack controller and/or external systems, opens and closes switches to connect and disconnect the power line.

In at least one embodiment, the power interface may receive power input directly from the power line and/or from an isolated power supply. The power interface may power the stack controller, via the stack bus, and/or further power the cell interfaces, via the link bus. In at least one embodiment, the stack controller and/or the power interface may receive instructions from external systems. In an embodiment, the battery management system includes a grid battery controller that controls a plurality of stack controllers that are connected in parallel. In at least one embodiment, the grid battery controller may be connected to a charger/inverter and/or another external system.

In at least one embodiment, the power interface includes at least a ground fault detector that detects unintentional current paths between the battery stack and a ground. In an embodiment, the ground fault detector may detect and/or measure small test currents from the most positive end of the battery stack to the ground and/or from the most negative end to the ground, which may indicate existence of a ground fault within the battery stack. The power interface may also determine the fault resistance and/or location based on the measurements. Additionally, the battery management system may also include a fault pilot signal generation/detection system that is independent of the control signal path. In at least one embodiment, the fault pilot signal is propagated along the stack bus and/or link bus, and absence of the fault pilot signal may indicate software failure, failure of processors and/or microcontrollers, loss of connection between the stack controller, cell interfaces, and/or the power interface. In at least one embodiment, the stack controller generates fault pilot signals that are embedded in the link bus and stack bus. The fault pilot signal may be suppressed by the cell interfaces, the stack controller, and/or other components of the battery management system to indicate a fault condition. The power interface may detect the absence of the fault pilot signal and accordingly control the switches. In an embodiment, external system may instruct the power interface whether or not to de-energize the switches in response to fault signals.

Any of the above embodiments may be used alone or together with one another in any combination. Inventions encompassed within this specification may also include embodiments that are only partially mentioned or alluded to or are not mentioned or alluded to at all in this brief summary or in the abstract.

### BRIEF DESCRIPTION OF THE FIGURES

In the following drawings like reference numbers are used to refer to like elements. Although the following figures depict various examples of the invention, the invention is not limited to the examples depicted in the figures.

FIG. 1 shows a block diagram of an embodiment of a battery management system;

FIG. 2 shows a block diagram of another embodiment of the battery management system in a hierarchical structure;

FIG. 3 shows a block diagram of an embodiment of the battery management system controlling an energy storage system;

FIG. 4 shows a block diagram of an embodiment of a cell interface that may be used in the battery management system;

FIG. 5 shows a block diagram of an embodiment of a stack controller that may be used in the battery management system;

FIG. 6 shows a block diagram of an embodiment of a power interface that may be used in the battery management system;

FIG. 7 shows a block diagram of an embodiment of fault detection using the fault pilot signal;

FIG. 8 shows a block diagram of an embodiment of detection of ground fault;

FIGS. 9A(1) and 9A(2) show a diagram of an embodiment of a ground fault detection circuit;

FIGS. 9B(1)-9B(5) show a diagram of an embodiment of a power interface circuit;

FIG. 9C shows a diagram of an embodiment of a fault pilot signal detector;

FIG. 10 is a flowchart of an embodiment of a method of using the system;

FIG. 11A is a flowchart of an embodiment of a method of ground fault detection process;

FIG. 11B is a flowchart of an embodiment of a method of fault detection using fault pilot signals; and

FIG. 12 is a flowchart of an embodiment of a method of assembling the battery management system.

### DETAILED DESCRIPTION

Although various embodiments of the invention may have been motivated by various deficiencies with the prior art, which may be discussed or alluded to in one or more places in the specification, the embodiments of the invention do not necessarily address any of these deficiencies. In other words, different embodiments of the invention may address different deficiencies that may be discussed in the specification. Some embodiments may only partially address some deficiencies or just one deficiency that may be discussed in the specification, and some embodiments may not address any of these deficiencies.

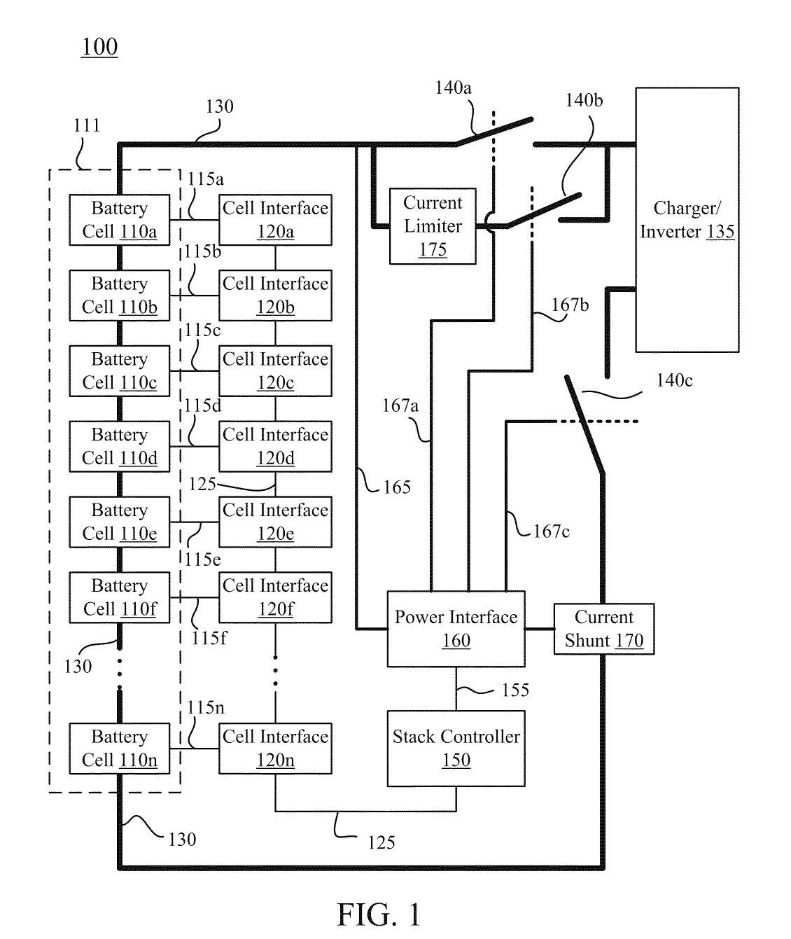

In general, at the beginning of the discussion of each of FIGS. 1-9 is a brief description of each element, which may have no more than the name of each of the elements in the one of FIGS. 1-9 that is being discussed. After the brief description of each element, each element is further discussed in numerical order. In general, each of FIGS. 1-12 is discussed in numerical order and the elements within FIGS. 1-12 are also usually discussed in numerical order to facilitate easily locating the discussion of a particular element. Nonetheless, there is no one location where all of the information of any element of FIGS. 1-12 is necessarily located. Unique information about any particular element or any other aspect of any of FIGS. 1-12 may be found in, or implied by, any part of the specification.

In various places in discussing the drawings a range of letters, such as a-n are used to refer to individual elements of various series of elements that are the same. In each of these series, the ending letters are integer variables that can be any number. Unless indicated otherwise, the number of elements in each of these series is unrelated to the number of elements in others of these series. Specifically, even though one letter (e.g. “c”) comes earlier in the alphabet than another letter (e.g., “n”), the order of these letters in the alphabet does not mean that the earlier letter represents a smaller number. The value of the earlier letter is unrelated to the later letter, and may represent a value that is greater the same or less than the later letter.

It should be understood that specific embodiments described herein are only used to explain at least one embodiment but not used to limit the present invention.

FIG. 1 shows a block diagram of an embodiment of a battery management system 100. Battery management system 100 includes at least a plurality of battery cells 110a-n, a battery stack 111, sensor conductors 115a-n, cell interfaces 120a-n, a link bus 125, a power line 130, a charger/inverter 135, switches 140a, 140b, and 140c, a stack controller 150, a stack bus 155, a power interface 160, an input conductor 165, conductors 167a, 167b, and 167c, a current shunt 170, and a current limiter 175. In other embodiments, the battery management system 100 may not have all of the elements or features listed and/or may have other elements or features instead of or in addition to those listed.

FIG. 1 shows a battery management system 100 that monitors and/or controls a stack of battery cells to input or output power via charger/inverter.

Battery management system 100 is a system that is configured to monitor the characteristics of a plurality of battery cells, and accordingly control the power inputting to and/or outputting from the battery cells. In at least one embodiment, battery management system 100 may receive instructions from external control systems to accordingly control the power inputting and/or outputting. In at least one embodiment, the battery management system 100 may detect fault conditions within the system and may respond to the fault conditions.

Battery cells 110a-n are electrochemical battery cells. In at least one embodiment, one cell in this specification refers to the smallest unit of energy storage distinguishable by the battery management system 100. In at least one embodiment, a battery cell may include one or more electrochemical cells connected in parallel. For example, a “1p” cell refers to a single electrochemical cell, while a “2p” cell refers to two electrochemical cells connected together in parallel. In at least one embodiment, the battery cells 110a-n may have different capacity. In another embodiment, some or all of the battery cells 110a-n may have similar capacity. Throughout this specification, the terms “battery cell,” “electrochemical cell,” and “cell” may be substituted one for the other to obtain different embodiments.

In at least one embodiment, a number of battery cells may form a group, while the battery cells in the same group are connected in series and managed together. For example, a “12s1p” group may include twelve “1p” cells connected in series, while a “16s2p” group may include sixteen “2p” cells connected in series. In at least one embodiment, at least one of the battery cells 110a-n may be replaced by a group of cells.

Battery stack 111 includes a number of battery cells 110a-n connected in series. In an embodiment, battery stack 111 may include one or more groups of cells connected in series. For example, a “5g14s2p” battery stack (which may also be referred to as a “70s2p” stack) may include five “14s2p” groups connected in series (or seventy “2p” cells connected in series. In at least one embodiment, the battery cells in the battery stack 111 are physically removable, together as a unit, from the battery stack 111. Throughout this specification, the terms “battery stack” and “stack” may be substituted one for the other to obtain different embodiments.

Sensor conductors 115a-n are conductors that communicatively connects the cell interfaces 120a-n to sensors that monitor the states of the cell batteries 110a-n, respectively. In at least one embodiment, sensor conductors 115a-n carry sensing signals (e.g., voltage of the cell batteries 110a-n and/or temperatures) to the cell interfaces 120a-n, respectively.

Cell interfaces 120a-n are interfaces that are configured to monitor and/or control connected battery cells 110a-n, respectively. In at least one embodiment, the cell interfaces 120a-n are communicatively connected with each other in series via a link bus. In at least one embodiment, the cell interfaces 120a-n passively balances the battery cells 110a-n to redistribute charging and/or discharging of the battery cells 110a-n. In at least one embodiment, a cell interface may monitor a number of batteries connected in series (e.g., a number of battery cells in a group). In at least one embodiment, the battery cells 110a-n may be connected in other orders to cell interfaces 120a-n. In at least one embodiment, the battery cells 110a-n and/or cell interfaces 120a-n may be arranged in other orders in the battery stack 111.

Link bus 125 is a cable that communicatively connects the stack controller to the connected cell interfaces 120a-n in series. In at least one embodiment, the link bus 125 provides a digital communications channel between the stack controller and the cell interfaces 120a-n. In at least one embodiment, the link bus 125 also provides power from the stack controller to the cell interfaces 120a-n.

Power line 130 is configured to carry electrical power into or out of the battery stack 111. In at least one embodiment, the battery cells 110a-n are connected in series in the power line 130, while the power line 130 is further connected to a load and/or charger/inverter that connect the battery stack 111 to a power grid.

Charger/inverter 135 include a charger that is configured to provide a charging current to the battery stack 111, and an inverter that is configured to change direct current (DC) of the battery stack 111 to alternating current (AC) and output the AC power. In at least one embodiment, the charger and inverter may be separately connected to the power line 130. In another embodiment, the charger and inverter are combined into a single entity.

Switch 140a is an electrical switch that controls the connection and disconnection of the power line 130 to the charger/inverter 135. In at least one embodiment, the switch 140a is a main switch controlling the power line 130. In an embodiment, the switch 140a is a contactor that may be controlled by the power interface that may switch contactor coil currents to break or make the power line 130. In at least one embodiment, the switches in this specification may include, but are not limited to, electronic relays, transistors (and/or other semiconductor switches or threshold devices), electromagnetic switches, electronic temperature switches, electronic time switches, current switches, voltage switches, multi directional switches, and/or frequency electrical switches.

Switch 140b is an electrical switch that is connected in parallel with the switch 140a. In an embodiment, the switch 140b is a pre-charge switch that controls a pre-charge circuit with a current limiter to limit in-rush current through the pre-charge circuit. In another embodiment, the switch 140b may be used to connect other battery stacks to battery stack 111 in parallel.

Switch 140c is an electrical switch that is connected in the power line 130 for controlling the connection of the battery stack with the load. In an embodiment, the switches 140c may be controlled by the power interface under the control of external equipment. ?

Stack controller 150 is configured to control the battery stack 111. In at least one embodiment, stack controller 150 is connected via link bus 125 to cell interfaces 120a-b that monitor the battery cells 110a-n, respectively. In at least one embodiment, the stack controller 150 is also communicatively connected to at least one power interface for controlling the switches 140a-c. In an embodiment, a stack controller controls a single battery stack.

Stack bus 155 is a cable that communicatively connects the stack controller 150 to the power interface. In at least one embodiment, the stack bus 155 also provides power from the power controller to the stack controller 150.

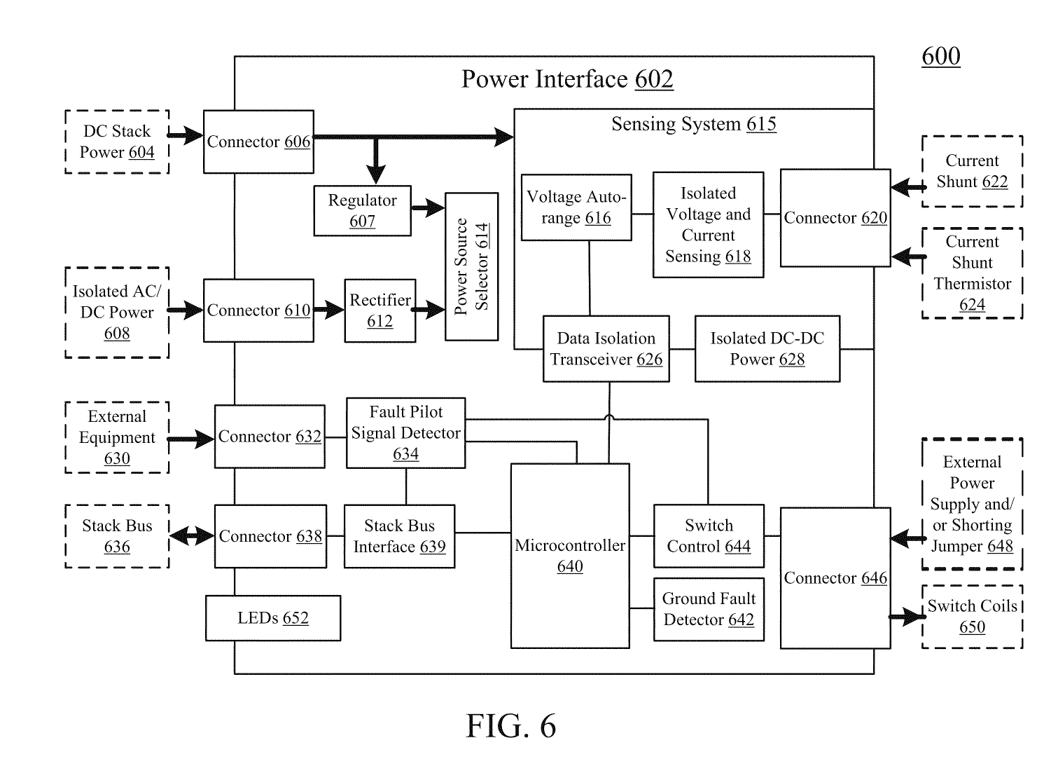

Power interface 160 is an interface that monitors current and voltage as well as to control the switches 140a-c. In at least one embodiment, the power interface 160 interfaces directly with high voltage and high current components along the power line 130. In at least one embodiment, the power interface 160 transmits the measurement of current and voltage of the power line 130 to the stack controller 150 for analysis. In at least one embodiment, the power interface 160 may detect fault conditions (e.g., ground fault, software failure, failure of processors/microcontrollers, loss of communications), and may control the switches 140a-c accordingly (e.g., de-energizing the coils of the switches 140a-n to open the switches 140a-c). The fault detection and switch control will be discussed in conjunction with FIGS. 6-9 and 11A-B.

Input conductor 165 is a conductor that connects a point in the power line 130 to the power interface 160. In at least one embodiment, the current may flow from the power line 130 directly to the power interface 160 directly via the input conductor 165, while the power interface 160 may measure the voltage in the power line 130.

Conductor 167a, 167b, and 167c are conductors that connect the power interface 160 to the switches 140a, 140b, and 140c, respectively. In at least one embodiment, the power interface 160 controls the current flow in the conductors 167a, 167b, and 167c to open and close the switches 140a, 140b, and 140c, respectively.

Current shunt 170 is a shunt or a resistor of accurately known resistance that is connected in the power line 130 in series with the load or charger/inverter 135 for accurately determining the current. In an embodiment, the resistance of current shunt 170 is small so as not to disrupt the power line 130. In at least one embodiment, a voltmeter is connected across the current shunt 170 to measure the voltage, and the power interface 160 receives the measurement of the voltage and calculates the current in the power line 130 using the voltage and the known resistance of the current shunt 170.

Current limiter 175 is a resistor that is connected in series with the switch 140b in the pre-charge circuit. In at least one embodiment, the current limiter 175 is connected to limit in-rush current through the pre-charge circuit.

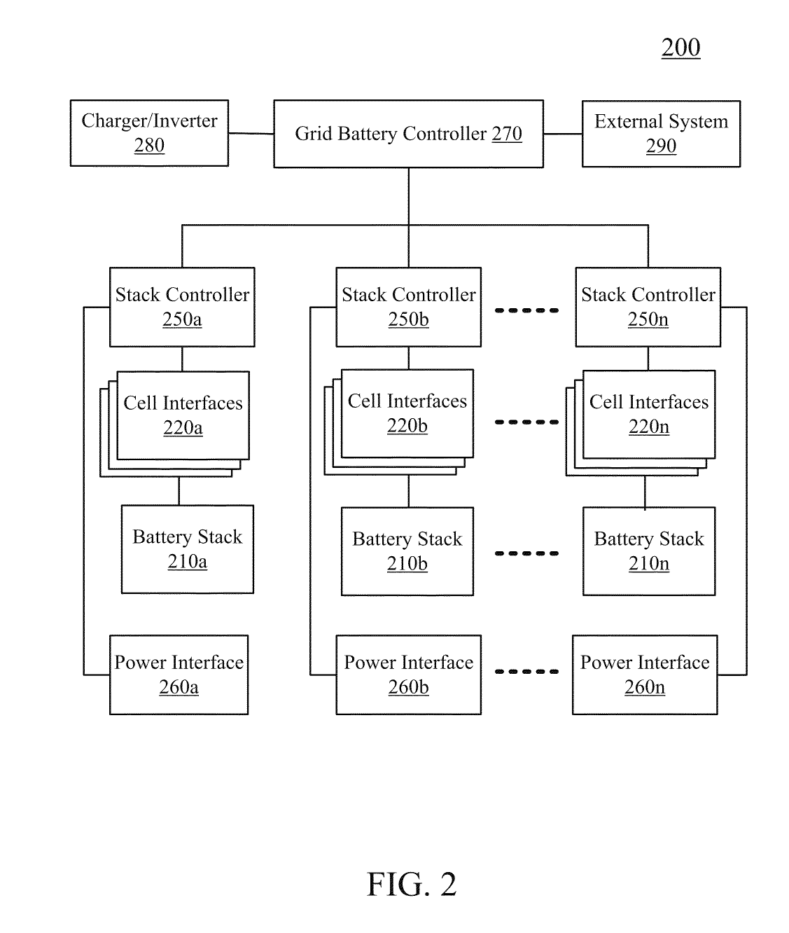

FIG. 2 shows a block diagram of another embodiment of the battery management system 100 in a hierarchical structure. The battery management system 200 includes at least battery stacks 210a-n, cell interfaces 220a-n, stack controllers 250a-n, power interfaces 260a-n, grid battery controller 270, charger/inverter 280, and external system 290. In other embodiments, the battery management system 200 may not have all of the elements or features listed and/or may have other elements or features instead of or in addition to those listed.

FIG. 2 shows a block diagram 200 of a grid battery controller that controls a plurality of stack controllers that are connected in parallel. Each of the plurality of stack controllers is connected to a power interface and a plurality of cell interfaces that monitors cells in a battery stack. The stack controllers are connected in parallel, and each stack controller may be individually controlled by a grid battery controller that controls the stack controllers.

Each of the battery stacks 210a-n may be an embodiment of the battery stack 111, which was discussed in conjunction with FIG. 1. Each of the cell interfaces 220a-n may include embodiments of the cell interfaces 120a-n, which were discussed in conjunction with FIG. 1. Each of the stack controllers 250a-n and power interfaces 260a-n may be an embodiment of the stack controller 150 and the power interface 160, respectively, which were discussed in conjunction with FIG. 1. Charger/inverter 280 may be an embodiment of the charger/inverter 135, which was discussed in conjunction with FIG. 1.

Grid battery controller 270 is configured to communicate and/or control a plurality of stack controllers in parallel. In an embodiment, a plurality of battery stacks are connected in parallel as a battery pack, while the grid battery controller 270 may serves as a supervisor for the battery pack and control each of the stack controllers in the battery pack. In at least one embodiment, the grid battery controller 270 is connected to each of the stack controllers 250a-n, via Ethernet or a Controller Area Network (CAN) bus. Alternatively, the grid battery controller 270 may communicate with the stack controllers 250a-n via (USB), Modbus (serial communications protocol), and/or other connections. In at least one embodiment, the grid battery controller 270 is connected to an external system and/or charger/inverter. Throughout this specification, the terms “pack supervisor” and “grid battery controller” may be substituted one for the other to obtain different embodiments.

External system 290 is an external system that includes, but is not limited to, an external control system, an external power supply, and/or other external systems and/or equipments. In at least one embodiment, external system 290 may be connected to the grid battery controller 270, via an industry standard bus (e.g., Ethernet, CAN bus, Modbus 485, Modbus TCP, etc.). Alternatively or additionally, the external system 290 may communicate with the grid battery controller 270, via a USB connection. In at least one embodiment, the external system 290 supervises and/or controls the grid battery controller 270, and/or may perform Supervisory Control and Data Acquisition (SCADA) functions, allowing battery stacks to be monitored and controlled remotely. In at least one embodiment, the external system 290 may include a SCADA system operating with coded signals over communication channels so as to provide control of battery stacks remotely. The control system using external system 290 may be combined with a data acquisition system by adding the use of coded signals over communication channels to acquire information about the status of the battery stacks for display and/or for recording functions.

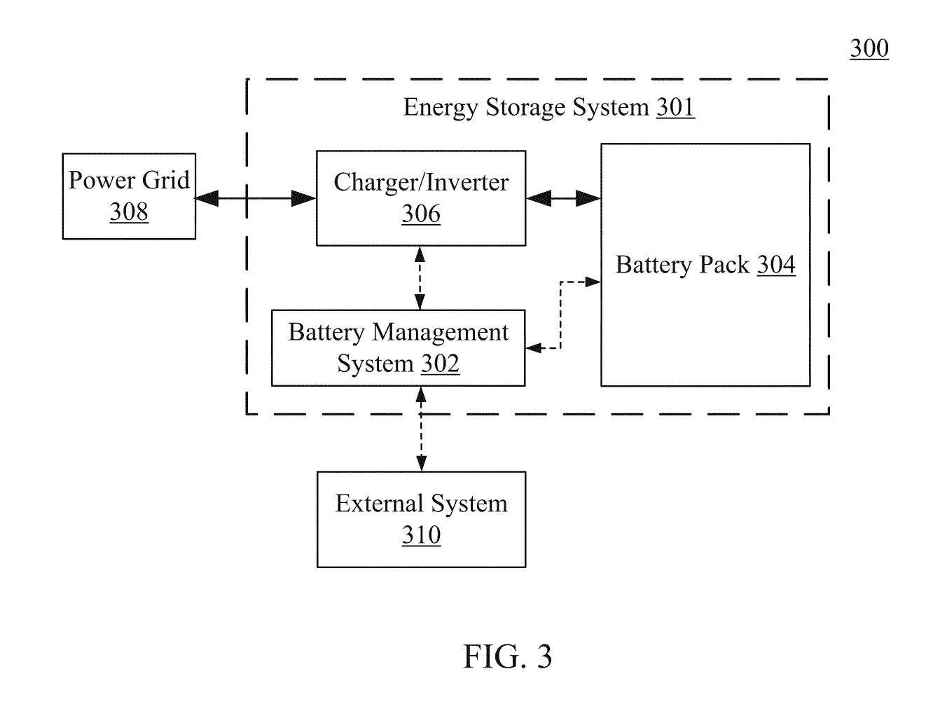

FIG. 3 shows a block diagram 300 of an embodiment of the battery management system 100 controlling an energy storage system. The diagram 300 shows at least an energy storage system 301, a battery management system 302, a battery pack 304, charger/inverter 306, a power grid 308, and an external system 310. In other embodiments, the system in diagram 300 may not have all of the elements or features listed and/or may have other elements or features instead of or in addition to those listed.

FIG. 3 shows a block diagram 300 of an energy storage system that is connected to a power grid, while the energy storage system is controlled by the battery management system 100. External systems may be connected to the battery management system 100 for supervisory control and/or data acquisition.

Energy storage system 301 is a system that stores electrical energy in at least a battery pack. In at least one embodiment, the energy storage system 301 may be charged from and/or output power to a power grid under the control of the battery management system 100.

Battery management system 302 may be an embodiment of the battery management system 100 and/or 200, which were discussed in conjunction with FIGS. 1 and 2. Charger/inverter 306 may be an embodiment of the charger/inverter 135 and/or 280, which were discussed in conjunction with FIGS. 1 and 2.

Battery pack 304 includes a plurality of battery stacks (e.g., one or more battery stacks 111) connected in parallel. For example, a “3x5g14s2p” Pack (which may also be referred to as a “3x70s2p” pack) includes three “5g14s2p” stacks connected in parallel. Throughout this specification, the terms “battery pack” and “pack” may be substituted one for the other to obtain different embodiments.

Power grid 308 is a power network for delivering electricity. In at least one embodiment, the power grid 308 carry electrical power from the energy storage system 301 to grid attached systems, telecom, robotics, specialty vehicles, etc. In at least one embodiment, power grid 308 may provide power to be stored in the energy storage system 301.

External system 310 may be an embodiment of the external system 290, which was discussed in conjunction with FIG. 2. In an embodiment, the external system 310 may be connected to the battery management system 302 (e.g., the stack controller 150, power interface 160, grid battery controller 270) for supervision, control, and/or data acquisition. In an embodiment, the external system 310 may reside within or behind the charger/inverter 306 and communicate with other control systems present on the power grid 308. In other applications, the battery management system 302 may control the charger/inverter directly while communicating with the external system 310 over a separate communication link.

In at least one embodiment, the solid lines indicate the flow of electrical power between the battery pack 304, charger/inverter 306, and/or power grid 308. The dashed lines indicate the communication between the battery management system 302, battery pack 304, charger/inverter 306, and/or external control system 310. In at least one embodiment, the battery management system 302 may be powered using the power in the energy storage system 301 and/or an isolated power supply.

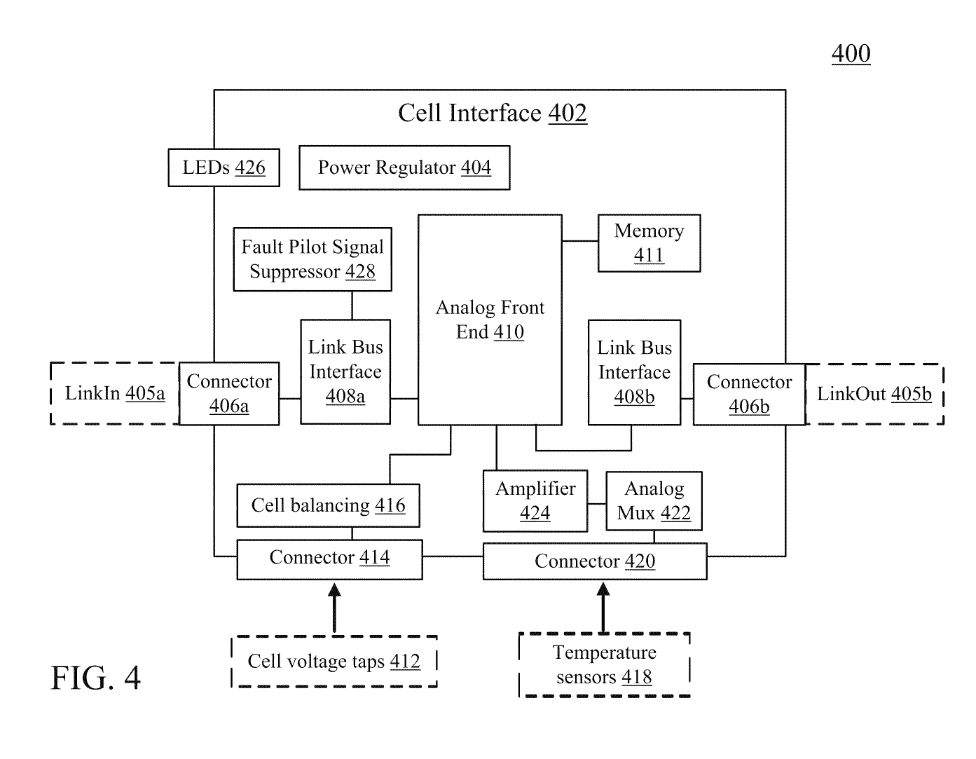

FIG. 4 shows a block diagram 400 of an embodiment of a cell interface that may be used in the battery management system 100. The system in diagram 400 includes at least a cell interface 402, a power regulator 404, a linkin 405a, a linkout 405b, connectors 406aand 406b, link bus interfaces 408aand 408b, an analog front end 410, a memory 411, cell voltage taps 412, a connector 414, cell balancing 416, temperature sensors 418, a connector 420, an analog mux 422, an amplifier 424, LEDs 426, and a fault pilot signal suppressor 428. In other embodiments, cell interface 402 may not have all of the elements or features listed and/or may have other elements or features instead of or in addition to those listed.

FIG. 4 shows a block diagram 400 of the components in the cell interfaces 120a-n. Cell interface 402 may be an embodiment of any of the cell interfaces 120a and 220a-n, which were discussed in conjunction with FIGS. 1 and 2, respectively. In at least one embodiment, the cell interface 402 may monitor multiple battery cells in a group and may be referred to as a multi-cell interface. In an embodiment, the cell interface 402 does not include high voltage and/or high current interfaces.

Power regulator 404 is a DC-DC regulator/converter that receives and regulates/converts the DC power received from the link bus 125 to power the components in the cell interface 402. In at least one embodiment, the power regulator 404 receives 24V DC power input from the link bus 125 and converts to other voltages.

Linkin 405ais an incoming end of the link bus 125 regarding the connected cell interface 402. In at least one embodiment, linkin 405a carry data communication as well as electrical power.

Linkout 405b is an outgoing end of the link bus 125 regarding the connected cell interface 402. In at least one embodiment, linkout 405bcarry data communication as well as electrical power. In at least one embodiment, a linkout of one cell interface may be connected to a linkin of another cell interface, so as to connect a plurality of cell interfaces in series using the link bus 125.

Connectors 406a and 406b are connectors that connect Linkin 405a and linkout 405b of the link bus 125, respectively, to the link bus interfaces 408a and 408b. In at least one embodiment, the connectors 406a and 406b are 4-pin connectors (2× isoSPI, V+, V−, with embedded fault signal).

Link bus interfaces 408aand 408bprovide power and/or communication between the link bus 125 and the cell interfaces 402. In at least one embodiment, the link bus interfaces 408a and 408b are communicatively connected to the analog front end to communicate sensing signals and/or other signals to the link bus 125. In an embodiment, the link bus interfaces 408a and 408b include isolated serial peripheral interface (isoSPI bus), LTC6804, DC blocking capacitors, and/or Ethernet transformer for communication.

Analog front end 410 is an analog front end (AFE) that is configured to interface a plurality of sensors to collect, process, and/or communicate to digital systems (e.g., analog to digital converter, processors, and microcontrollers). In at least one embodiment, the AFE 410 receives sensing signals about the voltage and temperature of the connected battery cell, and send data to the stack controller 150, via the link bus 125. In an embodiment, the AFE 410 is LTC6804 AFE. In an embodiment, the cell interface 402 may include more than one AFE as a population option to support the monitoring of a larger number of battery cells.

Memory 411 is a memory system that is connected to the AFE 410. In at least one embodiment, the memory 411 stores instructions for the AFE 410 to process and/or transmits signals. In an embodiment, the memory 411 may include electrically erasable programmable read-only memory (EEPROM) that may be attached to an I2C bus of AFE 410. The EEPROM may be used to store manufacturing information, build information, etc., which may be accessed, via the isoSPI bus. In other embodiments, the memory 411 may have different sizes and/or access methods.

Cell voltage taps 412 are connected to different points in the connected battery cell or group of cells (e.g., a battery group may include a number of battery cells connected in series) to measure and/or regulate the voltage output between two connected points. In an embodiment, cell voltage taps 412 supports up to 12 battery cells with one AFE 410 or up to 16 battery cells with two AFEs.

Connector 414 is a connector to which the cell voltage taps 412 are connected and transmits the voltage data to the cell interface 402. In at least one embodiment, the connector 414 includes 14-pin (7×2) or 18-pin (9×2) connectors.

Cell balancing 416 is passive balancing that is configured to redistribute charging and/or discharging cycles of the battery cells 110a-n. In an embodiment, the cell balancing 416 includes balancing resistor switches that are used to passively balance the battery cells based on the capacities of each cell. In an embodiment, energy is drawn from the most charged battery cell and is wasted as heat through the balancing resistors.

Temperature sensors 418 are temperature sensors that monitor the temperature of the battery cell or a group of battery cells monitored by the cell interface 402. In an embodiment, the temperature sensors 418 generate analog signals. In an embodiment, the temperature sensors 418 includes up to 8 temperature probes that are connected to the battery cells for monitoring of battery temperature. In other embodiments, the temperature sensors 418 include other numbers of temperature probes.

Connector 420 is a connector to which the probes of the temperature sensors 418 are connected to transmit the analog signals to the cell interface 402. In at least one embodiment, the connector 420 includes a 16-pin (8×2) connector.

Analog mux 422 is a multiplexer that selects one of several analog input signals received from the temperature sensors 418 and forwards the selected input into a single line to a signal amplifier.

Amplifier 424 is an electronic amplifier that amplifies the signals received from the temperature sensors 418 and transmits to the AFE 410. In at least one embodiment, the analog mux 422 and amplifier 424 serve as supporting circuitry to deliver the signals from the temperature sensors 418 to the AFE 410.

LEDs 426 are a number of LEDs that serve as indicators indicating the status of the cell interface 402. In an embodiment, LEDs 426 may display statuses, such as “Power” (indicating that power is being provided to the cell interface 402), “Activity” (indicating that an activity, such as signal sensing and/or fault suppressing, is being performed) and/or “Fault” (indicating that a fault was discovered). In at least one embodiment, the LEDs that may display the statuses “Power” and/or “Activity” are controlled by the power regulator 404 and/or the AFE 410. In at least one embodiment, the LED that may display “Fault” is controlled by the stack controller 150, which may send instructions, via link bus 125 to activate the “Fault” LED on the cell interface 402.

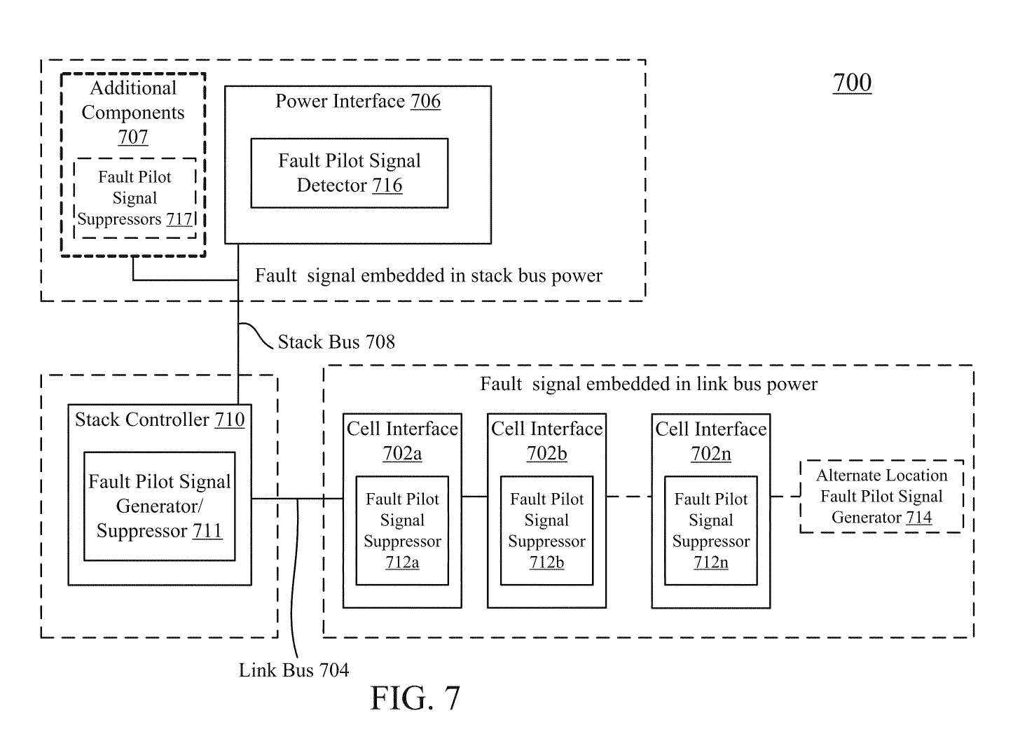

Fault pilot signal suppressor 428 is a signal suppressor that suppresses a fault pilot signal embedded in the link bus 125, indicating a fault condition in the cell interface (e.g., loss of connection from the voltage taps 412 and/or temperature sensors 418, AFE failure). In at least one embodiment, a pilot signal is transmitted (e.g., using a single frequency) over a communications system for supervisory, control, equalization, continuity, synchronization, or reference purposes. In an embodiment, the fault pilot signal is an AC signal that is embedded in DC power rail in the link bus and/or stack bus. The propagation and suppression of fault pilot signal will be discussed in conjunction with FIGS. 7-9 and 11B.

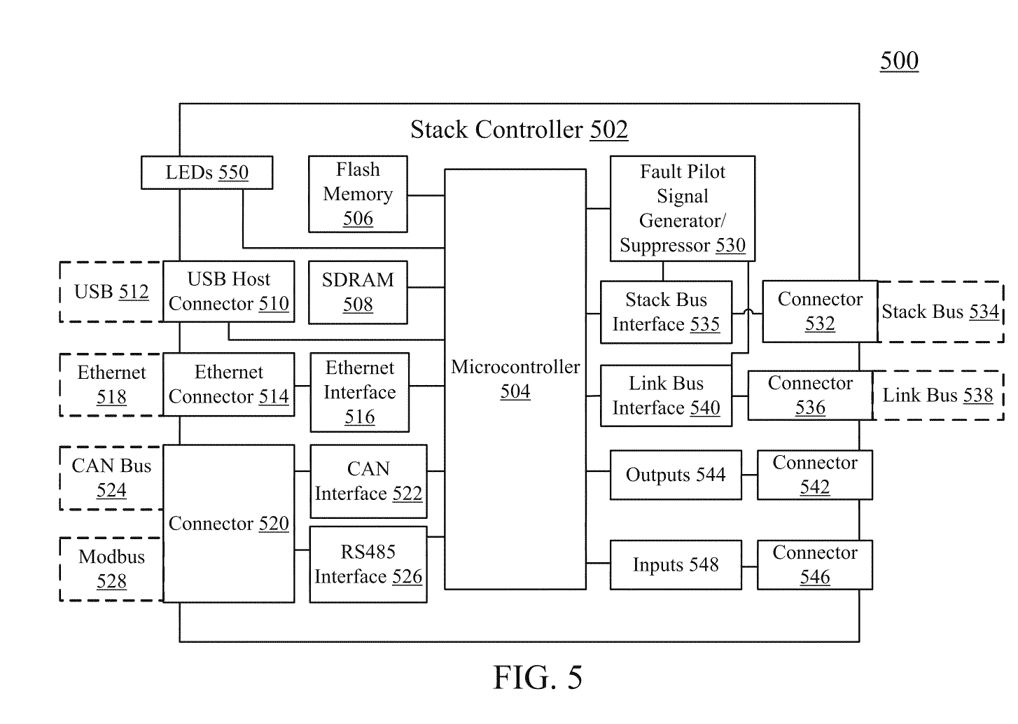

FIG. 5 shows a block diagram 500 of an embodiment of a stack controller that may be used in the battery management system 100. The system in diagram 500 includes at least a stack controller 502, a microcontroller 504, a flash memory 506, SDRAM 508, a USB host connector 510, USB 512, an Ethernet connector 514, Ethernet 518, a connector 520, a CAN interface 522, CAN bus 524, a RS485 interface 526, Modbus 528, fault pilot signal generator/suppressor 530, a connector 532, a stack bus 534, a stack bus interface 535, a connector 536, a link bus 538, a link bus interface 540, a connector 542, outputs 544, a connector 546, inputs 548, and LEDs 550. In other embodiments, the system in diagram 500 may not have all of the elements or features listed and/or may have other elements or features instead of or in addition to those listed.

FIG. 5 shows a block diagram 500 of the components in the stack controller 150. Stack controller 502 may be an embodiment of any of the stack controllers 150 and 250a-n, which were discussed in conjunction with FIGS. 1 and 2, respectively. In at least one embodiment, the stack controller 502 includes a communication interface to connect external systems. In at least one embodiment, the stack controller 502 may also expose diagnostics interfaces and/or debug serial port for use during development. Link bus 538 and stack bus 534 may be embodiments of the link bus 125 and stack bus 155, which were discussed in conjunction with FIG. 1.

Microcontroller (MCU) 504 is a microcontroller for controlling a plurality of modules and/or components in the stack controller 502. In at least one embodiment, the microcontroller 504 includes at least a microprocessor that is connected to a memory system. In at least one embodiment, the microcontroller 504 is configured to monitor and control the circuit boards of the connected cell interfaces and power interface.

Flash memory 506 is an electronic non-volatile computer storage medium that is connected to the microcontroller 504.

SDRAM 508 is a Synchronous Dynamic Random Access Memory (SDRAM) that is synchronized with system bus (e.g., SPI, CAN, USB, Ethernet, Modbus). In at least one embodiment, the flash memory 506 and SDRAM 508 serve as auxiliary memory systems as a population option. Alternatively or additionally, the stack controller 502 may include other systems.

USB host connector 510 is a Universal Serial Bus (USB)-A female connector to which peripherals and/or external systems may be plugged using a USB cable.

USB 512 is the USB connection used for communication between the stack controller 502 and external systems.

Ethernet connector 514 is a connector to which an Ethernet cable may be connected. In at least one embodiment, the Ethernet connector 514 is RJ-45 connector with activity LEDs.

Ethernet 518 is Ethernet standard communication connection used for communication between the stack controller 502 and external systems.

Connector 520 includes at least a connector and a terminator for Controller Area Network (CAN) bus with an isolating transceiver. In an embodiment, connector 520 may also include at least a connector, a terminator, and a transceiver for RS485 Modbus.

CAN interface 522 is an interface that receives data transmitted via CAN bus and transmit to the microcontroller 504.

CAN bus 524 is a controller area network communication. In at least one embodiment, the CAN bus 524 allows microcontroller 504 and other modules and/or circuits to communicate with each other without a host computer.

RS485 interface 526 is an interface that receives data transmitted, via Modbus, and transmits the data to the microcontroller 504.

Modbus 528 is a connector for communicating, via the Modbus serial communications protocol, via which external systems are connected to the stack controller 502. In at least one embodiment, the external system 290 and/or 310 may be connected to the stack controller 502, via Modbus 528.

Fault pilot signal generator/suppressor 530 includes at least a fault pilot signal generator/emitter that generates AC signal that is embedded in the DC power (e.g., the 24V DC supply) in the link bus 125 and stack bus 155. In at least one embodiment, the fault pilot signal generator includes an AC emitter. In an embodiment, the AC emitter of the fault pilot signal generator produces a 50 kHz sinusoidal pilot signal, with a magnitude of approximately 1V pk-pk at the source, AC coupled through moderately high impedance onto power bus for the stack bus 534 and/or the link bus 538.

In at least one embodiment, the fault pilot signal generator/suppressor 530 also include a fault pilot signal suppressor that suppresses the AC fault pilot signal to indicate a fault condition (e.g., software failure, failure of microcontroller 504, loss of connection with cell interfaces and/or power interface). In at least one embodiment, to suppress the AC fault pilot signal, the fault pilot signal suppressor includes, for example, a 4.7 μF/50V capacitor with a 4.7 kΩ resistor in series across bus power rail (e.g., in the stack bus 534 and/or link bus 538), and uses a Metal-Oxide-Semiconductor Field-Effect Transistor (MOSFET) to short the resistor in order to signal the fault. The capacitor in the fault pilot signal suppressor would then effectively dampen the fault pilot signal, and the absence of the fault pilot signal would be detected by a fault pilot signal detector (e.g., in the power interface 160). The fault pilot signal generation and suppression will be discussed in conjunction with FIGS. 7-9 and 11B.

Connector 532 is a connector to which the stack bus 534 is connected. In at least one embodiment, the connector 532 is a 6-pin connector (CAN+, CAN−, termination, V+, V−/Shield, with embedded fault pilot signal).

Stack bus interface 535 provides power and/or communication between the stack bus 534 and the stack controller 502. In an embodiment, the stack bus interface 535 receives 24V DC power input from the stack bus 534. In at least one embodiment, the stack bus interface 535 is communicatively connected to the microcontroller 504 to transmit data received via stack bus 534 to the microcontroller 504. In an embodiment, the stack bus interface 535 communicates via CAN bus with cell interfaces and/or power interface. In an embodiment, the stack bus interface 535 is connected to the fault pilot signal generator/suppressor 530, so that the generated fault pilot signal may be embedded in the stack bus 534.

Connector 536 is a connector to which the link bus 538 is connected. In at least one embodiment, the connector 536 is a 4-pin connector (2×isoSPI, V+, V−, with embedded fault signal).

Link bus interface 540 delivers power and/or allows communication between the link bus 538 and the stack controller 502. In at least one embodiment, the link bus interface 540 outputs 24V DC power with short-circuit protection via the link bus 538. In an embodiment, the link bus interface 540 uses an isolated Serial Peripheral Interface (isoSPI) bus to communicate with cell interfaces. The isolated isoSPI provides a two wire connection or four wire connection, via which link bus 538 and stack controller 502 can communicate in full duplex mode while remaining isolated from one another (to protect from surges in the power) during the communication. In at least one embodiment, the link bus interface 540 is communicatively connected to the microcontroller 504 to transmit data received via link bus 538 to the microcontroller 504. In an embodiment, the link bus interface 540 is connected to the fault pilot signal generator/suppressor 530, so that the generated fault pilot signal may be embedded in the link bus 538.

Connector 542 is a connector to which optional digital inputs may be connected. In at least one embodiment, the connector 542 is an 8-pin connector.

Outputs 544 are optional digital outputs that may be connected to the microcontroller 504 of the stack controller 502. In at least one embodiment, outputs 544 provide interface for the microcontroller 504 to output signals to other components of the battery management system 100 and/or external system.

Connector 546 is a connector to which optional digital outputs may be connected. In at least one embodiment, the connector 546 is an 8-pin connector.

Inputs 548 are optional digital inputs that may be connected to the microcontroller 504 of the stack controller 502. In at least one embodiment, inputs 548 provide interface for external system and/or other components of the battery management system 100 to input signals to the microcontroller 504.

LEDs 550 are a number of LEDs that serve as indicators indicating the status of stack controller 502. In an embodiment, LEDs 550 may display statuses, such as “Power” (indicating that power is being provided to the stack controller) “Activity” (indicating that an activity, such as signal processing and/or fault testing, is being performed) and/or “Fault” (indicating that a fault was discovered). In at least one embodiment, the LEDs 550 are controlled by the microcontroller 504.

FIG. 6 shows a block diagram 600 of an embodiment of a power interface that may be used in the battery management system 100. The system in diagram 500 includes at least a power interface 602, DC stack power 604, a connector 606, a regulator 607, isolated AC/DC power 608, a connector 610, a rectifier 612, a power source selector 614, a sensing system 615, voltage auto-range 616, isolated voltage and current sensing 618, a connector 620, a current shunt 622, a current shunt thermistor 624, data isolation transceiver 626, isolated DC-DC power 628, external equipment 630, a connector 632, a fault pilot signal detector 634, a stack bus 636, a connector 638, a stack bus interface 639, a microcontroller 640, a ground fault detector 642, switch control 644, a connector 646, external power supply or shorting jumper 648, switch coils 650, and LEDs 652. In other embodiments, the power interface 602 may not have all of the elements or features listed and/or may have other elements or features instead of or in addition to those listed.

FIG. 6 shows a block diagram 600 of the components in the power interface 602.

Power interface 602 may be an embodiment of any of the power interfaces 160 and 260a-n, which were discussed in conjunction with FIGS. 1 and 2, respectively. The power interface 602 may be connected to dual power sources to power the components in the battery management system 100. The power interface 602 provides data collection interfaces which receive a high voltage input from the battery stack 111 and input from the current shunt 170, so as to measure overall battery stack voltage and current. The power interface 602 may detect fault conditions and accordingly control the switches 140a-c. The power interface 602 may be connected to and/or controlled by external equipments and/or external systems.

Current shunt 622 and stack bus 636 may be embodiments of the current shunt 170 and stack bus 155, respectively, which were discussed in conjunction with FIG. 1.

DC stack power 604 is a high voltage power directly received from the battery stack 111 via the input conductor 165.

Connector 606 is a connector to which the input conductor 165 is connected for delivering electrical supply directly from the power line 130 to the power interface 602. In at least one embodiment, the connector 606 is a 3-pin connector.

Regulator 607 is a DC-DC regulator/converter that regulates/converts the high voltage DC power input from the battery stack 111 to other voltages (e.g., low voltages) in order to power the components in the power interface 602.

Isolated AC/DC power 608 is an isolated power supply from a standard line transformer or battery. In an embodiment, the Isolated AC/DC power 608 provides 24V AC or DC power.

Connector 610 is a connector to which the isolated AC/DC power 608 is connected for supplying isolated power to the power interface 602. In at least one embodiment, the connector 610 is a 2-pin connector.

Rectifier 612 is a rectifier that converts alternating current (AC), which is received from the isolated AC/DC power 608, to DC power.

Power source selector 614 is a selector including at least switches for selecting either the DC stack power 604 or the isolated AC/DC power 608 as the power source for the power interface 602. In at least one embodiment, the power source selector 614 selects the higher of the DC stack power 604 and isolated AC/DC power as the operating source of the power interface 602. In at least one embodiment, the components of the power interface 602 (as well as the stack controller 502 and/or cell interfaces 402) accept a nominal 24V DC power.

Sensing system 615 is a high precision current and/or voltage sensing system. In at least one embodiment, the sensing system 615 measures voltage of the battery stack 111 and current via the current shunt 170. In at least one embodiment, the sensing system 615 transmits sensing signals to the microcontroller in the power interface 602 for analysis.

Voltage auto-range 616 automatically adjusts the scaling/range of the input voltage so that the measurement of the voltage uses the full precision of the sensing system 615. In at least one embodiment, the voltage auto-range 616 includes at least an auto-ranging digital multimeter. In at least one embodiment, the voltage auto-range 616 allows the sensing system 615 to measure voltage input with high dynamic range.

Isolated voltage and current sensing 618 isolates voltage sensing (e.g., measuring the input voltage using voltage auto-range 616) and current sensing (e.g., via the current shunt 622).

Connector 620 is a connector to which the current shunt 622 and current shunt thermistor are connected. In at least one embodiment, the connector 620 is a 4-pin connector, 2-pin for connecting the current shunt 622 and 2-pin for the thermistor. In at least one embodiment, the sensing system 615 includes a current shunt interface with high dynamic range and low offset error current for precision coulomb counting that calculates remaining capacity in the battery stack 111 by measuring the current entering (charging) or leaving (discharging) the battery stack 111.

Current shunt thermistor 624 is an electrical resistor that is dependent on temperature that is used to measure and/or control the current shunt 622p. In at least one embodiment, the current shunt thermistor 624 may be used as an inrush current limiter and/or overcurrent protector.

Data isolation transceiver 626 is a transceiver 626 that galvanically isolates the data communication between the sensing system 615 and the microcontroller from the rest of the power interface 602.

Isolated DC-DC power 628 galvanically isolates power for powering the sensing system 615 from the rest of the power interface 602.

External equipment 630 is external to the battery management system 100 and can be connected to the power interface 602 for controlling the system. In an embodiment, the coils of the switches 140a-c will not be energized by the battery management system 100 unless the external equipment 630 connects two points in a connector in the power interface 602. In at least one embodiment, the external equipment 630 (by opening a switch in the external equipment 630) may force de-energizing of switch coils to cause all switches 140a-c to open (to disconnect the power line 130). In an embodiment, it is desirable and/or required to use the external equipment 630 to disconnect the power line 130 in some fault situation not detected by the battery management system 100. Alternatively, if the external equipment 630 is not used or required, a shorting jumper may be connected to the two points in the connector where the external equipment was connected. In an embodiment, disconnecting the shorting jumper may cause all switches 140a-n to open.

Connector 632 is a connector to which the external equipment 630 is connected. In at least one embodiment, the connector 646 includes three points/pins, allowing the external equipment 630 to be connected in different ways in different situations for controlling the switches 140a-c.

Fault pilot signal detector 634 is a signal detector that detects the AC fault pilot signal that is embedded in the stack bus 636. In at least one embodiment, an absence of the fault pilot signal may indicate that the fault pilot signal is suppressed by a fault pilot signal suppressor (e.g., fault pilot signal suppressor 428 in the cell interface 402, fault pilot signal generator/suppressor 530 stack controller 150), indicating a fault condition. In at least one embodiment, the fault pilot signal detector 634 monitors the AC fault pilot signal and detects disappearance of the AC signal. In an embodiment, the fault pilot signal detector 634 includes an envelope detector tuned for 50 kHz. In an embodiment, the power interface 602 may take direct hardware action (e.g., en-energizing coils of the switches 140a-c to open up the switches 140a-c) based upon the detected absence of fault pilot signal.

In at least one embodiment, the fault pilot signal detector 634 outputs signals to the microcontroller of the power interface 602, which may send instructions to the switch control for controlling the switches 140a-c. Alternatively or additionally, the battery management system 100 includes a de-energizing response behavior that may de-energize the switch coils in response to the detection of absence of fault pilot signal, independent of the microcontroller of the power interface 602. In at least one embodiment, the fault pilot signal detector 634 may output directly to the switch control, and the switch control can cause immediate de-energizing of the switch coils, with no software interaction required. In at least one embodiment, the direct connection between the fault pilot signal detector 634 and the switch control allows detection and control of the switches 140a-c using hardware, independent of the software (e.g., of the microcontroller and/or processor) in the battery management system 100.

In at least one embodiment, the de-energizing response behavior may be defeated by the external equipment 630 (or a shorting jumper), via the connector 632 to which the external equipment 630 is connected to control the switch operation. In at least one embodiment, a user may choose via the external equipment 630 whether the detection of absence of fault pilot signal would directly cause opening of the switches 140a-c. In an embodiment, the connection of the external equipment 630 to the connector 632 may prevent the fault detection by the fault pilot signal detector 634 from directly de-energizing the coils of the switches 140a-c, while still allowing the microcontroller of the power interface 602 to instruct the switch control to control the switches 140a-n. Alternatively, the connection of the external equipment 630 to the connector 632 may permit the power interface 602 to directly de-energize the coils of the switches 140a-c in response to detected absence of fault pilot signal.

Connector 638 is a connector to which the stack bus 636 is connected. In at least one embodiment, the connector 638 is a 6-pin connector (CAN+, CAN−, termination, V+, V−/Shield, with embedded fault pilot signal).

Stack bus interface 639 provides power and/or communication between the power interface 602 and the stack controller 150 via the stack bus 636. In an embodiment, the stack bus interface 639 provides 24V DC for powering the stack controller 150 and/or cell interfaces 120a-n. In at least one embodiment, the stack bus interface 639 is communicatively connected to the microcontroller. In an embodiment, the stack bus interface 639 includes a CAN bus interface that is used to communicate with the stack controller 150. In an embodiment, the stack bus interface 639 is connected to the fault pilot signal detector 634, which monitors fault pilot signal embedded in the stack bus 636.

Microcontroller 640 is a microcontroller that controls the components in the power interface 602. In at least one embodiment, the microcontroller 640 includes at least a microprocessor that is connected to a memory system. In at least one embodiment, the microcontroller 640 is configured to monitor the voltage, current, and/or charge (e.g., coulomb counting), and/or reports to the stack controller 150. In at least one embodiment, the microcontroller 640 includes integrated Random-access Memory (RAM), Flash, CAN, and/or serial interfaces. In at least one embodiment, the microcontroller 640 includes diagnostics interfaces and/or a debug serial port for use during development.

In at least one embodiment, the microcontroller 640 monitors and reports ground fault and/or absence of fault pilot signals to a switch control that controls the switches 140a-c. Additionally, the fault pilot signal detector 634 may directly output to the switch control, and the switch control may control the switches 140a-c without requiring control instructions received from the microcontroller 640. In at least one embodiment, software control (e.g., via the microcontroller 640) of the switches 140a-n is slower but more flexible than hardware control (e.g., using the external equipment 630 and/or direct connection between the fault pilot signal detector 634 and switch control). In an embodiment, some delay may be included in either suppressing the fault pilot signal or detecting a suppressed fault pilot signal to give the software control paths time to take action. In an embodiment, the microcontroller 640 detects the fault signal, and on a fault de-assertion, implements a timer that waits for ten seconds, for example, before energizing any switch coil. If the control path via the microcontroller 640 has had a sufficient time window to act and has failed to do so (or in case of microcontroller failure and/or disconnection of communication in the battery management system 100), the switches 140a-c can be controlled using hardware without the software interaction in the microcontroller 640.

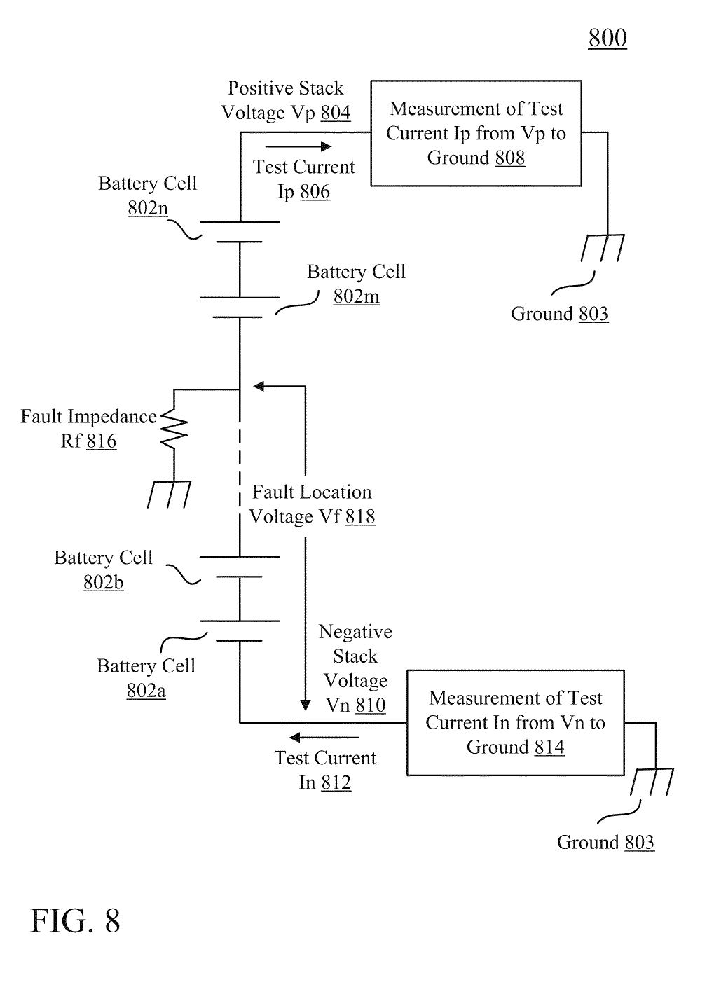

Ground fault detector 642 is a detector that detects unintentional current paths between the batter stack 111 and the ground. The ground fault detection will be discussed in conjunction with FIGS. 8, 9, and 11A.

Switch control 644 controls the coils of the switches 140a-c. In at least one embodiment, the switch control 644 may control the power to the coils that is directly supplied from the power interface 602. In at least one embodiment, the coil requirements are within the power supply capabilities of the power interface 602. Alternatively, the coils of switches 140a-c may be powered by external power supply, while the switch control 644 may switch currents driven from the external power supply.

Connector 646 is a connector to which the switch coils, external power supply, and/or shorting jumper may be connected. In at least one embodiment, the connector 646 is a 12-pin connector. In at least one embodiment, the connector 646 includes at least 8-pins for switching of up to 4 high-current contactors with configurable functions.

External power supply or shorting jumper 648 may include an external power source for energizing the switch coils of the switches 140a-c. In an embodiment, the external power supply may be on the circuit board of the power interface 602 or off the circuit board. In at least one embodiment, switch or shorting jumper from external equipment may be connected to the connector 646 for the user to select whether fault detection causes de-energizing of switch coils.

Switch coils 650 are coils of the switches 140a-c that are controlled by the switch control 644. In an embodiment, the switch coils 650 are stipulated to be 24 VDC operating voltage, with pull-in currents up to 1 A, 2 A, or 4 A, for example. In an embodiment, the switch coils 605 may be the coils in contactors such as Gigavac GX11, Gigavac HX22, and/or Gigavac GX110.

LEDs 652 are a number of LEDs that serve as indicators indicating the status of the power interface 602. In an embodiment, the LEDs 652 may display statues, such as “Power” (indicating that power is being provided by the battery stack 111), “Activity” (indicating that activity, such as fault testing and/or sensing activity, is being performed) and/or “Fault” (indicating a fault condition was discovered). In at least one embodiment, the LEDs 652 are controlled by the microcontroller 504.

FIG. 7 shows a block diagram 700 of an embodiment of fault detection using the fault pilot signal. The system in diagram 500 includes at least cell interfaces 702a-n, a link bus 704, a power interface 706, additional components 707, a stack bus 708, a stack controller 710, a fault pilot signal generator/suppressor 711, fault pilot signal suppressor 712a-n, alternate location fault pilot signal generator 714, fault pilot signal detector 716, and a fault pilot signal suppressors 717. In other embodiments, the system in diagram 700 may not have all of the elements or features listed and/or may have other elements or features instead of or in addition to those listed.

FIG. 7 shows a block diagram 700 of fault detection in addition to the detection of ground fault in the battery stack 111. In at least one embodiment, the battery management system includes a fault pilot signaling mechanism that is redundant to the software control mechanism of the switches 140a-c (e.g., activation and deactivation of the switch coils using the microcontroller 640). In at least one embodiment, the fault detection using fault pilot signal is a hardware based detection that is independent of the control communication path. In at least one embodiment, fault detection using the fault pilot signal may detect software failure, failure of processors/microcontrollers, and loss of connection between the power interface and the stack controller and/or between the stack controller and the cell interfaces.

Cell interface 702a-n may be embodiments of any of the cell interfaces 120a-n, 220a-n, and 402, which were discussed in conjunction with FIGS. 1, 2, and 4, respectively. Power interface 706 may be an embodiment of any of the power interfaces 160, 260a-n, and 602, which were discussed in conjunction with FIGS. 1, 2, and 6, respectively. Stack controller 710 may be an embodiment of any of the stack controllers 150, 250a-n, and 502, which were discussed in conjunction with FIGS. 1, 2, and 6, respectively. Link bus 704 and stack bus 708 may be embodiments of the link buses 125 and/or 538 and stack buses 155, 534, and/or 636, which were discussed in conjunction with FIGS. 1, 5, and 6. Fault pilot signal generator/suppressor 711 may be an embodiment of the fault pilot signal generator/suppressor 530, which was discussed in conjunction with FIG. 5. Each of the fault pilot signal suppressor 712a-n may be an embodiment of the fault pilot signal suppressor 428, which was discussed in conjunction with FIG. 4.

The fault pilot signal generator/suppressor 711 is an embodiment of the fault pilot signal generator/suppressor 530, which was discussed in conjunction with FIG. 5. In at least one embodiment, the fault pilot signal generator/suppressor 711 emits AC signals along the power rail of the stack bus 708 and/or the link bus 704, while the fault pilot signal suppressors 712a-n in the cell interfaces 702a-n may suppress the fault pilot signal to indicate a fault condition. The fault pilot signal generator/suppressor 711 may also suppress the AC signal in the stack bus 708. In an embodiment, a cable disconnection between the fault pilot signal generator/suppressor 711 in the stack controller 710 and the fault pilot signal detector in the power interface 706 will also be detected as a fault.

Additional components 707 include additional systems and/or components that may be included in the battery management system 100. In at least one embodiment, the additional components 707 include one or more fault pilot signal suppressor that may suppress the fault pilot signal embedded in the stack bus 708.

Alternate location fault pilot signal generator 714 is a fault pilot signal generator in an alternative location, instead of residing in the stack controller 710. In an embodiment, the alternate location fault pilot signal generator 714 is a link bus dongle that plugs into the linkout 405b port of the last cell interface 702n. In an embodiment, the dongle in the alternate location fault pilot signal generator 714 includes an AC emitter/oscillator that is powered from the link bus 704, and emits AC fault pilot signal along the link bus 704. In an embodiment, loss of connection in the link bus 704 at any of the cell interfaces 702a-n can be detectable by the fault pilot signal detector 716 as a fault condition. In an embodiment, when the AC emitter in the stack controller 710 emits signals, the AC emitter in the alternate location fault pilot signal generator 714 is disabled (vice versa).

Fault pilot signal detector 716 is an embodiment of the fault pilot signal detector 634, which was discussed in conjunction with FIG. 6.

Fault pilot signal suppressors 717 are fault pilot signal suppressors that are installed in the additional components 707. In at least one embodiment, the fault pilot signal suppressors 717 function in a similar way as the fault pilot signal suppressors 712a-n.

FIG. 8 shows a block diagram 800 of an embodiment of detection of ground fault. Diagram 800 shows at least battery cells 802a-n, positive stack voltage Vp 804, test current Ip 806, measure test current Ip from Vp to ground 808, ground 803, negative stack voltage Vn 810, test current In 812, measure test current In from Vn to ground 814, fault impedance Rf 816, and fault location voltage Vf 818. In other embodiments, the ground fault detection diagram 800 may not have all of the elements or features listed and/or may have other elements or features instead of or in addition to those listed.

FIG. 8 shows a diagram 800 of the detection of ground fault using the ground fault detector 644, by measuring test currents from the most positive end of the battery stack to the ground and from the most negative end to the ground.

Battery cells 802a-n are embodiments of the battery cells 110a-n, which were discussed in conjunction with FIG. 1. In at least one embodiment, battery cells 802a-n form a battery stack, within which one or more faults may exit at some point.

Ground 803 is a common return path for electric current, serving as constant potential reference point from which voltages are measured. In at least one embodiment, in a grounded system (such as home AC wiring), the ground 803 provides a return path back to the source for the current to prevent user contact with dangerous voltage. In at least one embodiment, when no grounding is intentionally made in a battery system (e.g., in the battery stack), a single ground fault would not carry current, since the ground 803 provides no return path to the battery stack. However, the ground fault within the battery stack may present a potentially dangerous situation, as personnel contacting any portion of the battery stack while simultaneously contacting the ground 803 could provide a current path through themselves if there is no ground provided.

Positive stack voltage Vp 804 is the voltage of the most positive end of the battery stack that includes battery cells 802a-n in series relative to the ground. In at least one embodiment, the power interface 602 detects ground fault via the positive stack voltage Vp 804 and the most negative end of the battery stack, but not directly testing individual cells within the stack.

Test current Ip 806 is a small test current that is passed through a test load connected between the positive stack voltage Vp 804 to the ground 803, if a ground fault exists in the battery stack. If no ground fault exits, no test current Ip 806 will be detected.

Measurement of test current Ip from Vp to ground 808 is performed by amplifying the small test current Ip 806 and then converting the signal by an analogue-to-digital converter in the microcontroller 640 in the power interface 602.

Negative stack voltage Vn 810 is the voltage of the most negative end of the battery stack that includes battery cells 802a-n in series relative to the ground 803.

Test current In 812 is a small test current that is passed through a test load connected between the negative stack voltage Vn 810 to the ground 803, if a ground fault exists in the battery stack. If no ground fault exits, no test current In 812 will be detected.

Measurement of test current In from Vn to ground 814 is performed by amplifying the small test current In 812 and then converting the signal by an analogue-to-digital converter in the microcontroller 640 in the power interface 602.

Fault impedance Rf 816, if a fault exits in the battery stack, is resistance at some point in the battery stack that results from the fault. In at least one embodiment, if fault impedance Rf816 exits, the ground fault detector 642 would detect at least one of the test currents Ip 806 and In 812.

Fault location voltage Vf 818 is a voltage of the fault impedance Rf816 relative to the most negative end Vn 810. In at least one embodiment, the fault location voltage Vf 808 is calculated by the power interface 602 to indicate the location of the fault in the battery stack.

In at least one embodiment, a single fault within the battery stack may be detected using the following mechanism. The ground fault detector 642 attempts to pass a small test current from Vp 804 to Vf 818 through Rf 816, using ground 803 as the path. If no test current Ip 806 is detected, the detection may indicate two situations: either Rf 816 is infinite (i.e., there is no fault), or Vp 804=Vf 818 (i.e., the fault Rf 816 exists at the most positive end of the cell stack). The ground fault detector 642 then attempts to pass a small test current from Vn 810 to Vf 818 through Rf 816, using ground 803 as the path. If no test current In 812 is detected, the detection may indicate two situations: either Rf 816 is infinite (i.e., there is no fault), or Vn 810=Vf 818 (i.e., the fault Rf 816 exists at the most negative end of the battery stack). If both of test currents Ip 806 and In 812 are zero, indicating no passage of current, the results indicate that no ground fault exists between the Vp 804 and Vn 810 of the battery stack. If at least one of the Ip 806 and In 812 is detected to present a measured current, indicating the existence of a fault Rf 816, then the magnitude of the fault impedance Rf 816 and the location of the fault (based on Vf 818) may be calculated. In order to calculate the Rf 816 and Vf 818, the power interface 602 must determine and/or obtain the voltage of entire battery stack.

In an embodiment when at least one of Ip 806 and In 812 is not zero, the magnitude of the fault impedance Rf 816 may be calculated using the formula: Rf=(Vp−Vn)/(Ip+In), while Vp−Vn is the stack voltage that is known to the power interface 602. The location of Rf 816 may be further determined by calculating the voltage relative to Vn 810 using the formula: Vf=In*Rf.

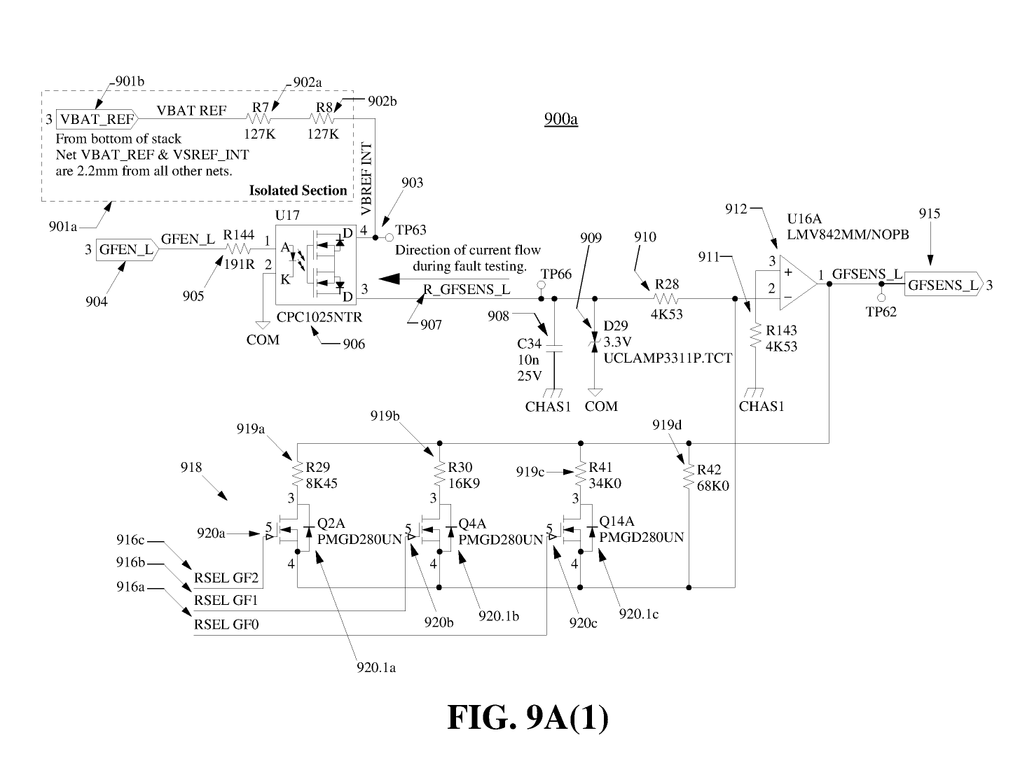

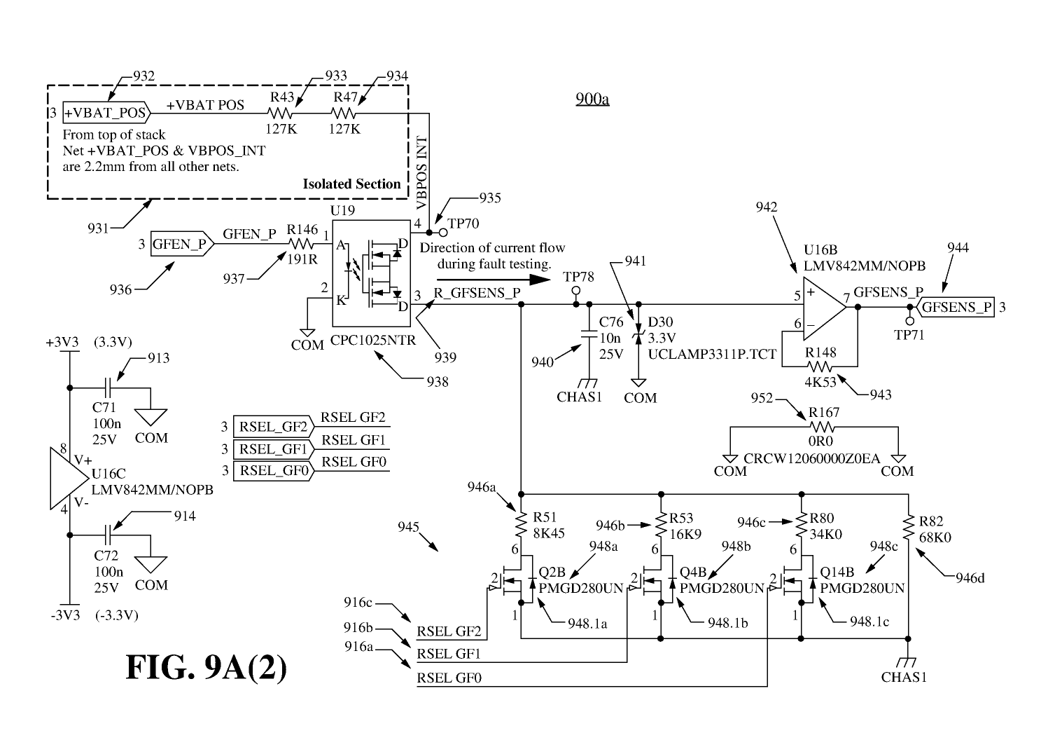

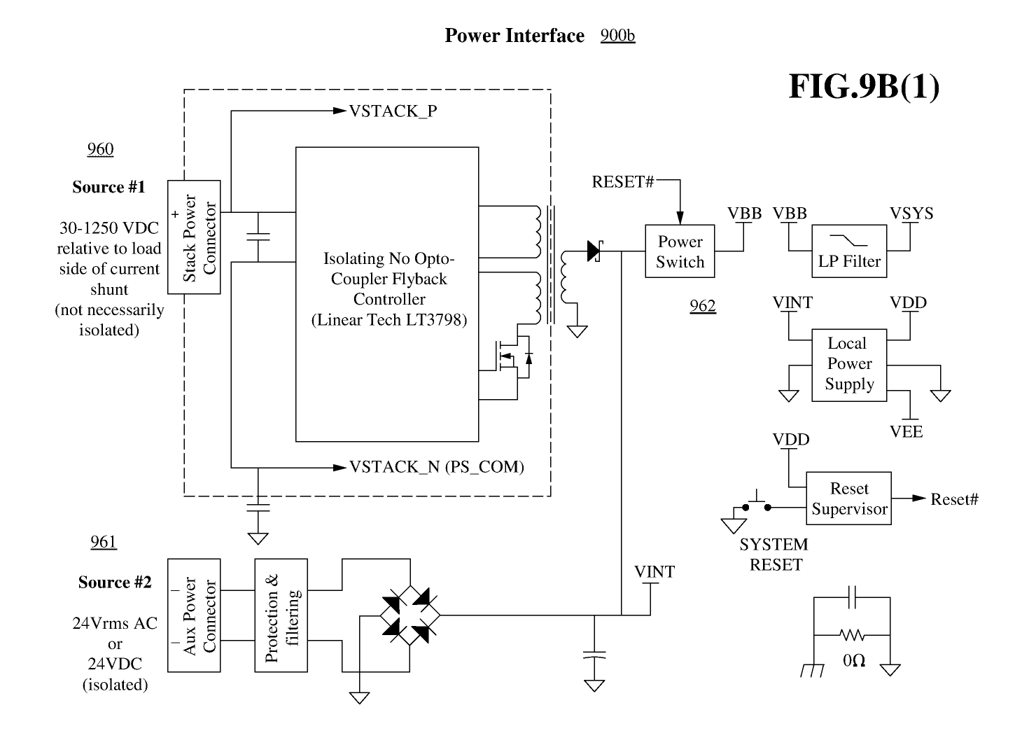

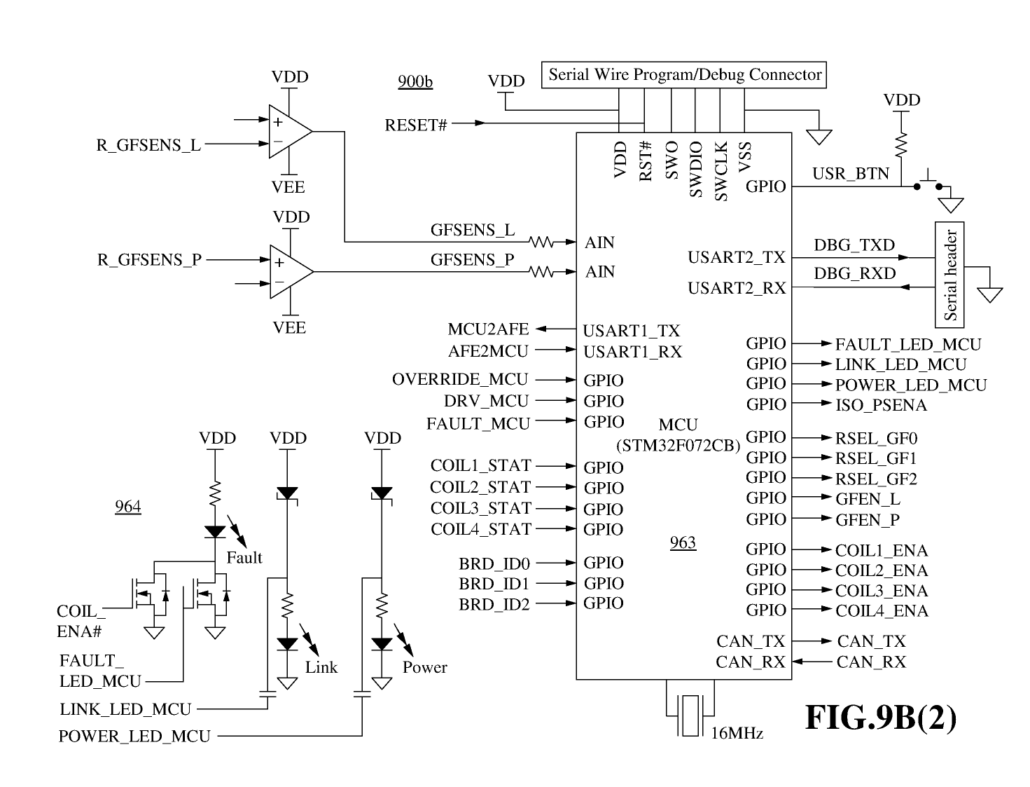

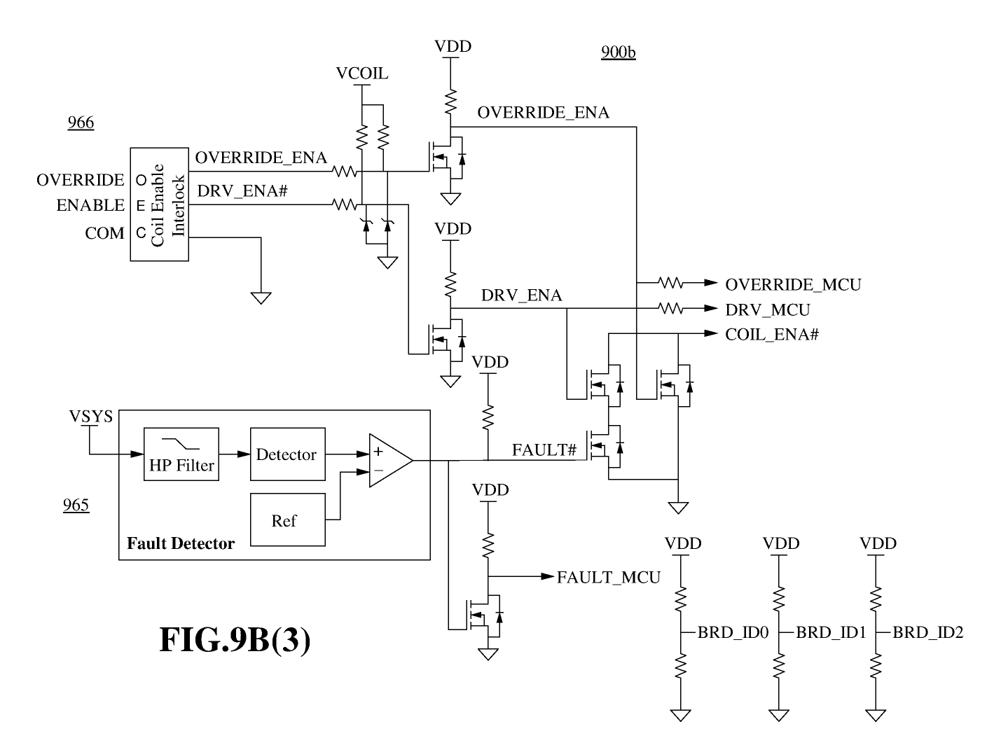

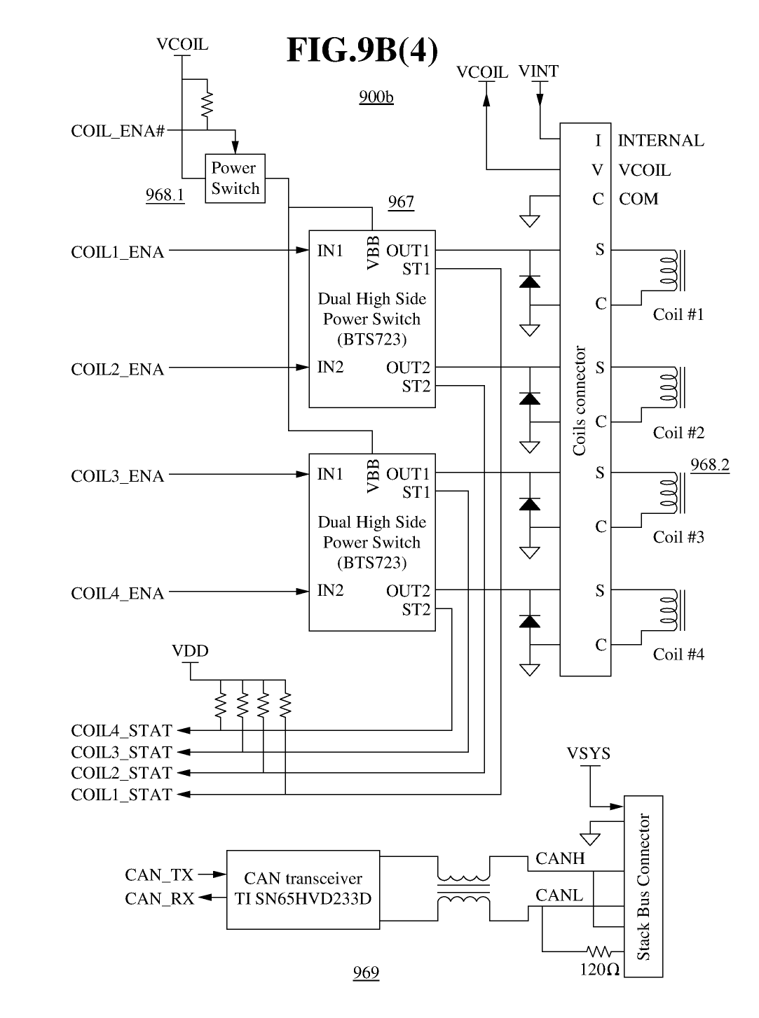

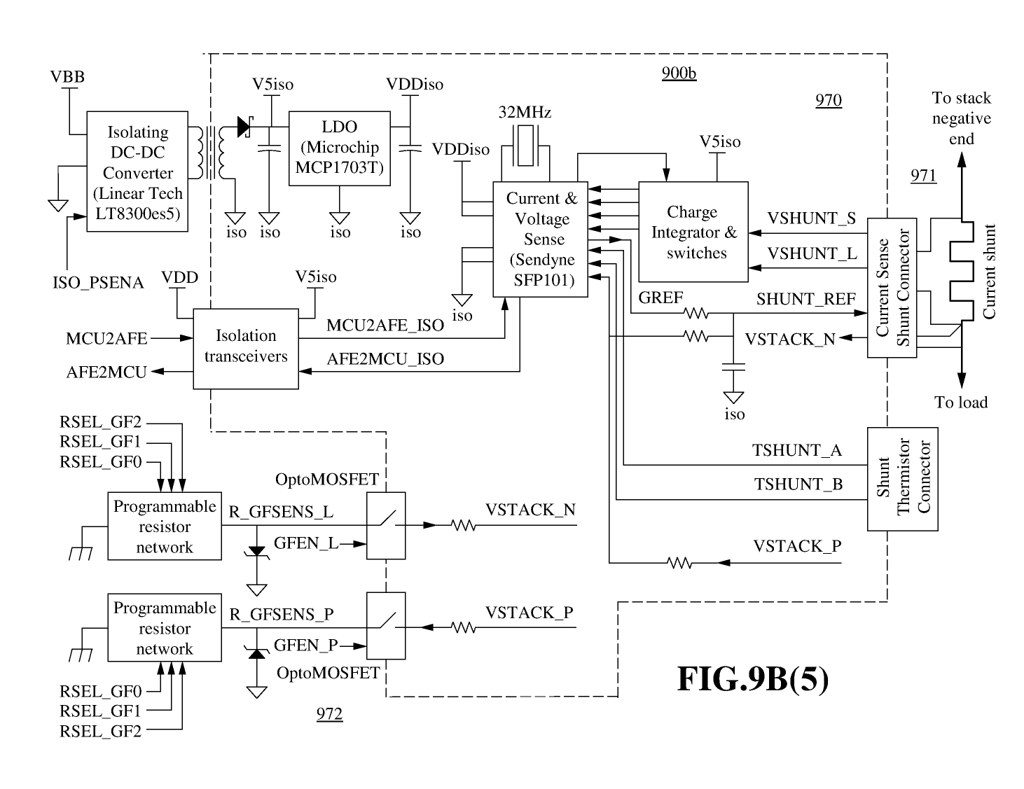

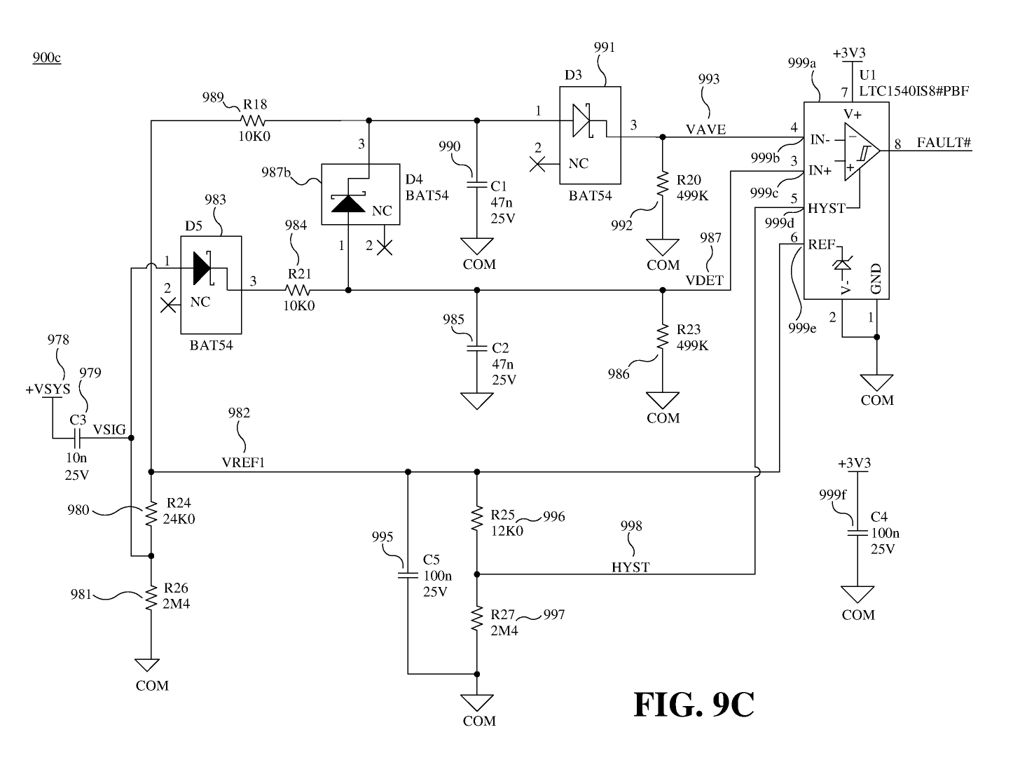

FIGS. 9A(1) and 9A(2) show a diagram of an embodiment of a ground fault detection circuit 900a. In other embodiments, the circuit 900a may not have all of the elements or features listed and/or may have other elements or features instead of or in addition to those listed.

FIGS. 9A(1) and 9A(2) show switch U19 and other elements. Switch U19 is a switch that turns on the test current Ip 806 from the most positive end of the battery stack (+VBAT_POS). In at least one embodiment, the switch U19 is controlled by the microcontroller 640 of the power interface 602, via signal GFEN_P. The test current Ip 806 will flow only if a ground fault exists somewhere in the battery stack other than at the most positive end. If a test current Ip 806 flows, Ip 806 causes a positive voltage (with respect to the ground 803) to be raised in the programmable voltage divider network formed by resistors R43, R47, and R82 in parallel with a combination of resistors R51, R53, and R80, as selected by the microcontroller 640 via signals RSEL_GF2, RSEL_GF1, and RSEL_GF0. The abovementioned positive voltage is buffered by the amplifier U16B onto signal GFSENS_P, and converted to a digital value by the analogue to digital converter in the microcontroller 640. To suppress noise or transient spikes which may appear on the battery stack from damaging or stressing the amplifier, transient voltage suppressor D30 clamps the amplifier input voltage at about ±3.3V.

In at least one embodiment, the MOSFETs Q2B, Q4B, and Q14B are used to select a combination of resistors to make up the programmable voltage divider. The drain-source diodes are the intrinsic body diodes instead of physically separate components.

In at least one embodiment, switch U17 turns on the test current. In 812 from the negative stack voltage Vn 810 of the battery stack (VBAT_REF). The switch U17 is controlled by the microcontroller 640 of the power interface 602, via signal GFEN_L. The test current In 812 will flow only if a ground fault exists somewhere in the battery stack other than at the most negative end. If a test current In 812 flows, In 812 causes a positive voltage (with respect to the ground 803) to be produced at the output of amplifier U16A onto signal GFSENS_L, with the amplifier gain set by the programmable voltage divider network formed by resistors R7, R8, R28, and R42 in parallel with a combination of resistors R29, R30, and R41, as selected by the microcontroller 640 via signals RSEL_GF2, RSEL_GF1, and RSEL_GF0. The voltage at GFSENS_L is converted to a digital value by the analogue to digital converter in the microcontroller 640. To suppress noise or transient spikes which may appear on the battery stack from damaging or stressing the amplifier, transient voltage suppressor D29 clamps the amplifier input voltage at about ±3.3V.

In at least one embodiment, the MOSFETs Q2A, Q4A, and Q14A are used to select a combination of resistors to make up the programmable voltage divider. The drain-source diodes shown in FIGS. 9A(1) and 9A(2) are intrinsic diodes formed by the MOSFET structure instead of physically separate components.

In at least one embodiment, amplifiers Q16A and Q16B are powered from a bipolar power supply. The positive supply is taken from the power interface's +3.3V power rail (+3V3), filtered by C17. The negative supply is generated by a switched-capacitor voltage inverters at U18, which produces approximately −3.3V from the +3.3V supply. The output supply from U18 is filtered by C74, ferrite bead FB2, and C72. The amplifiers used in the circuit of FIGS. 9A(1) and 9A(2) (U16A and U16B) require a bipolar power supply (i.e., both positive and negative power supply voltages) in order to produce a linear output. The switched capacitor inverter at U18 is being used to generate the negative power supply for the amplifiers. Zero ohm resistor R167 ensures that the circuitry reference common level (COM) is at the same potential as earth or chassis ground against which ground fault is tested (CHAS).

In at least one embodiment, the gain of these amplifiers is a function of the resistor combinations as set by the microcontroller through digital signals RSEL_GF2, RSEL_GF1, & RSEL_GF0. In FIGS. 9A(1) and 9A(2), U16A has a negative gain, as the current direction will be out of the circuit into the most negative end of the battery stack. U16B is configured as a unity gain buffer, (i.e., it has a gain of +1), and presents a buffering high impedance to the fault test current network (R43, R47, R51, R53, R80, R82) while presenting a low impedance signal source to the analogue-to-digital converter. A particular combination is chosen for each of the two current tests to maximize the resolution of the analogue-to-digital converter without saturating it. When testing the negative stack voltage Vn 810 of the stack, the current In 812 flowing in the test impedance (R7+R8+R28) in series with the unknown fault impedance is V(GFSENS_L)/Rx. When testing the positive stack voltage Vp 804 of the stack, the current Ip 806 flowing in the test impedance (R43+R47+Rx) in series with the unknown fault impedance is V(GFSENS_H)/Rx. Therefore, when a battery stack has a total known potential of Vstack volts, the system may calculated the magnitude Rfault ohms of a single ground fault in the battery stack and the location the ground fault that is situated Vfault volts above the negative stack voltage Vn 810, using the following formulas. Formula I: Vfault/(R7+R8+R28+Rfault)=V(GFSENS_L)/Rx. Formula II: (Vstack−Vfault)/(R43+R47+Rx+Rfault)=V(GFSENS_H)/Rx.

In at least one embodiment, two tests, one from the positive stack voltage Vp 804 and one from the negative stack voltage Vn 810 of the battery stack, are performed for detecting the ground fault within the battery stack. If a fault exists, the fault will be at a lower potential than the positive stack voltage Vp 804, and at a higher potential than the negative stack voltage Vn 810, and therefore the test currents Ip 806 and In 812 will be in opposite directions. In an embodiment, to meet the requirements of the analogue-to-digital converter which can only read positive signals, one of the two test currents Ip 806 and In 812 needs to be inverted.

FIGS. 9B(1)-9B(5) show a diagram of an embodiment of a power interface circuit 900b. In other embodiments, the circuit 900b may not have all of the elements or features listed and/or may have other elements or features instead of or in addition to those listed.

FIG. 9C shows a diagram of an embodiment of a fault pilot signal detector 900c. The fault pilot signal detector 900c may be an embodiment of any of the fault pilot signal detector 634 and 716, which were discussed in conjunction with FIGS. 6 and 7, respectively. In other embodiments, the fault pilot signal detector 900c may not have all of the elements or features listed and/or may have other elements or features instead of or in addition to those listed.

In at least one embodiment, the fault pilot signal detector 900c receives an input (e.g., +VSYS in FIG. 9C). The input may include a DC voltage of approximately 24 volts, with a sinusoidal fault pilot signal of amplitude approximately Vp=2 volts peak-to-peak and a frequency of 55 kHz added to the DC voltage (in other embodiments other frequencies and voltages could be used instead). Capacitor C3 and resistor R26 form a high pass filter, allowing only the sinusoidal portion of the fault pilot signal to pass, and adding the sinusoidal portion to a DC reference level of VREF1*R26/(R24+R26). In an embodiment, reference VREF1 is a stable DC reference level voltage produced by the LTC1540 at U1, and filtered by C5. The resulting signal is rectified by D5 (forward voltage drop of about Vf=0.24V) (in other embodiments other voltages could be used instead), and low-pass filtered by R21 and C2, to produce the signal VDET which will have amplitude as calculated in (VREF1*R26/(R24+R26)+Vp/2−Vf)*R23/(R21+R23). The resulting signal is compared by comparator U1 to a reference voltage VAVE, equal to (VREF1−Vf)*R20/(R18+R20). Component values have been chosen such that R23/(R21+R23) equals R20/(R18+R20). The Vf terms are the forward voltages of D5 and D3, and may be considered equal. U1 therefore compares VREF1*R26/(R24+R26)+Vp/2 compared to VREF1.

In an embodiment, if Vp=0 (i.e., if the fault pilot signal is suppressed), then the comparison reduces to VREF1*R26/(R24+R26) compared to VREF1. And thus the right side (IN− on U1) is greater in magnitude than the left side (IN+ on U1), and the output of U1 will be at a low voltage (FAULT#) indicating detection of a fault.

If Vp=2Vp−p (i.e., if the fault pilot signal is not suppressed), then the comparison reduces to VREF1*R26/(R24+R26)+1 compared to VREF1. Values for R24 & R26 are chosen so that the right side (IN− on U1) is lower in magnitude than the left side (IN+ on U1), and the output of U1 will be at a high voltage (FAULT#) indicating no detection of a fault.

In an embodiment, U1 is implemented with a small amount of hysteresis, to prevent the output signal from oscillating if the fault pilot signal is close to the detection threshold.

The circuit shown in FIG. 9C is just one example of a signal detector that may be used for detecting the fault pilot signal. There are many other ways of constructing a signal detector that could be used instead of the circuit shown in FIG. 9C.

### Method of Using

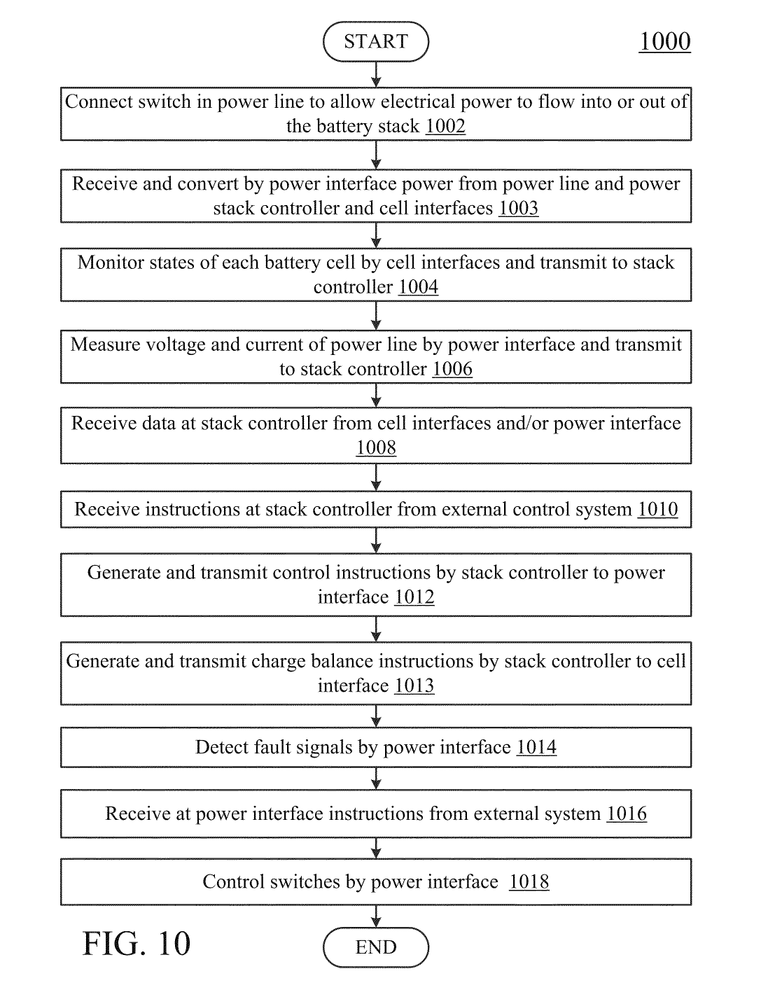

FIG. 10 is a flowchart of an embodiment of a method 1000 of using the battery management system 100.

In step 1002, the switches 140a and/or 140c in the power line 130 are connected to allow electrical power to flow from into or out of the battery stack 111.

In step 1003, the power interface 160 receives power of high voltage via the input conductor 165 from the power line 130, and converts the power to low voltage to power the power interface. As part of the step 1003, the power interface 160 transmits electrical power via the stack bus 155 to power the stack controller 150, and the electrical power is further carried via the link bus 125 to power the cell interfaces 120a-n.

In step 1004, cell interfaces 120a-n monitor characteristics of battery cells 110a-n, respectively. As part of the step 1004, the cell interfaces 120a-n transmit the data about the battery cells 110a-n via the link bus 125 to the stack controller 150.

In step 1006, the power interface 160 measures the voltage and current (by detecting the current shunt 170) of the power line 130. As part of the step 1006, the power interface 160 transmits data about the voltage and current via the stack bus 155 to the stack controller 150.

In step 1008, the stack controller 150 receives data from the cell interfaces 120a-n and/or power interface 160.

In step 1010, the stack controller 150 receives instructions from external control system 310 via Ethernet 518, CAN bus 524, USB 512, and/or Modbus 528.

In step 1012, the stack controller 150 generates control instructions based on data received from cell interfaces 120a-n and/or power interface 160, and/or instructions received from external control system 130. As part of the step 1012, the stack controller 150 transmits the control instructions via the stack bus 155 to the power interface 160.

In step 1013, the stack controller 150 generates charge balance instructions based on the measurements of the voltage of each battery in a cell and transmits to the connecting cell interface.

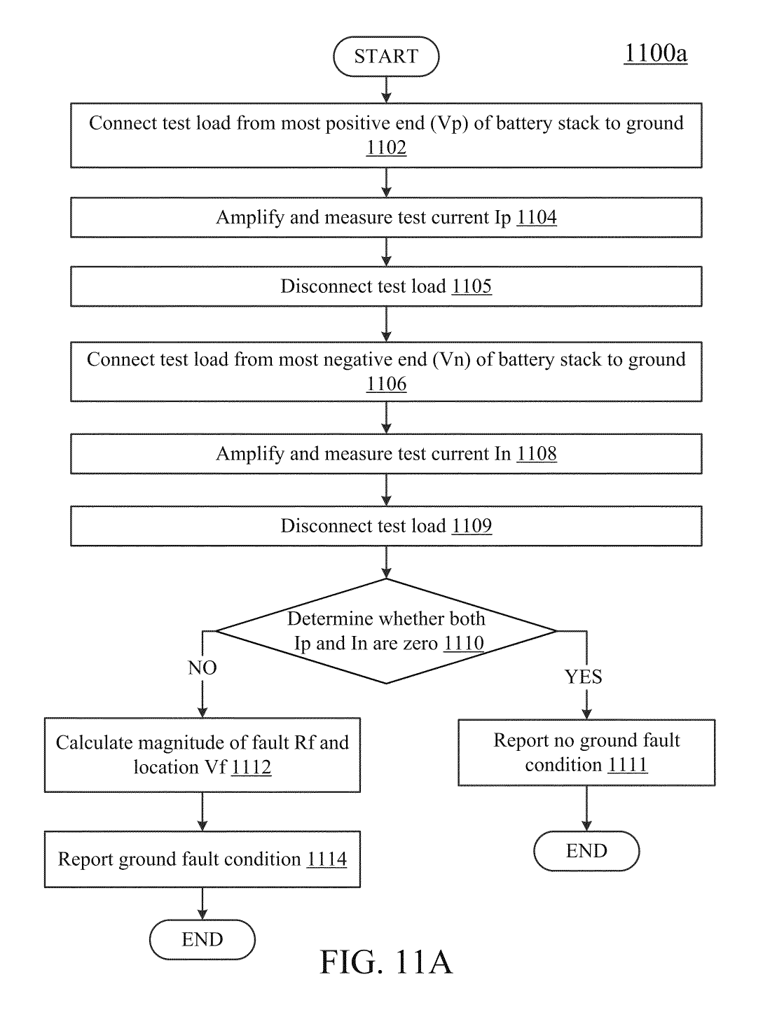

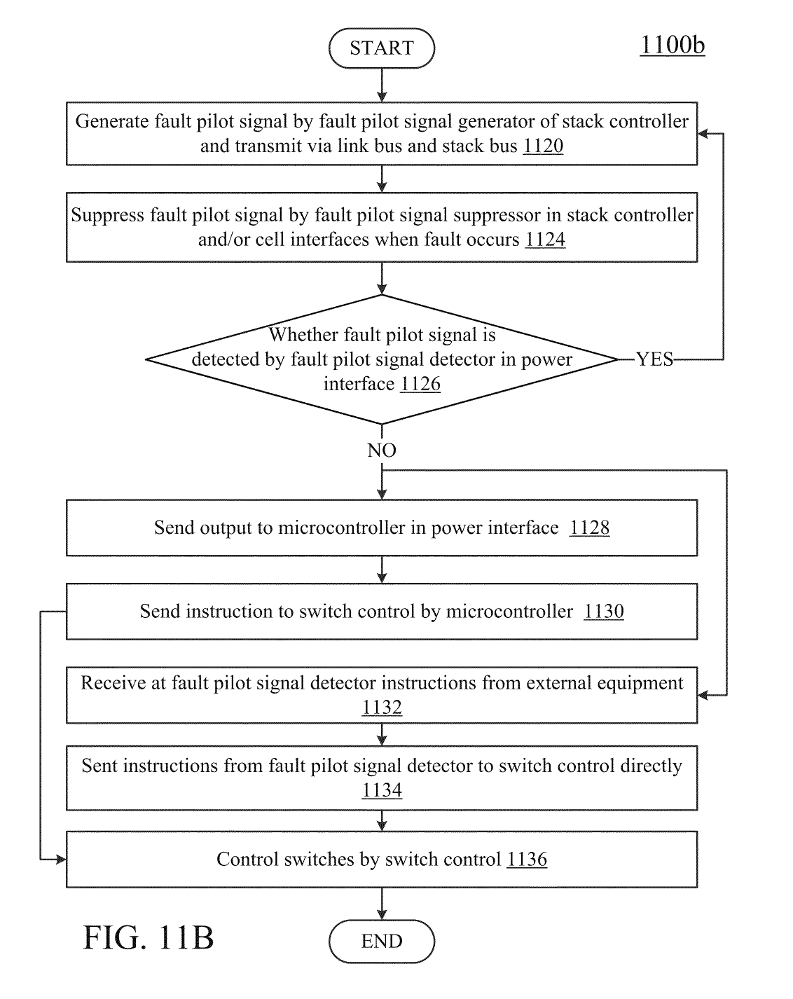

In step 1014, the power interface 160 detects fault signals. As part of step 1014, the ground fault detector 642 of the power interface 160 detects ground fault signals by detecting unintentional current paths between the battery stack 111 and the ground 803. As part of step 1014, the fault pilot signal detector 634 of the power interface 160 detects suppression of fault pilot signals embedded in the stack bus 155. The ground fault detection and fault pilot signal detection will be discussed in FIGS. 11A and 11B.

In step 1016, the power interface 160 receives instructions from external system that may include external power supply and/or shorting jumper 648. In an embodiment, the power interface 160 receives instructions from external systems whether to de-energize coils of the switches 140a-c in response to fault detection.

In step 1018, the power interface 160 controls the switches 140a-c based on fault signal detection and/or instructions received from the stack controller 150 and/or external system.

In an embodiment, each of the steps of method 1000 is a distinct step. In another embodiment, although depicted as distinct steps in FIG. 10, step 1002-1018 may not be distinct steps. In other embodiments, method 1000 may not have all of the above steps and/or may have other steps in addition to or instead of those listed above. The steps of method 1000 may be performed in another order.

FIG. 11A is a flowchart of an embodiment of a method 1100a of ground fault detection process.

In step 1102, the most positive end of the battery stack is connected to the ground 803. As part of the step 1102, a number of resistors are placed as test load in the path from Vp 804 to the ground 803.

In step 1104, the test current Ip 806 is amplified and measured by the microcontroller 640.

In step 1105, the test load is disconnected.

In step 1106, the most negative end of the battery stack is connected to the ground 803. As part of the step 1106, a number of resistors are placed as test load in the path from Vn 810 to the ground 803.

In step 1108, the test current In 812 is amplified and measured by the microcontroller 640.

In step 1109, the test load is disconnected.

In step 1110, the microcontroller 640 of the power interface 160 determines whether both Ip 806 and In 812 are zero. In yes, the microcontroller 640 determines that there is no ground fault in the battery stack, and the method 1100 proceeds to step 1111. If no, the value of the Ip 806 and/or In 812 indicates a ground fault in the battery stack, and the method 1100 proceeds to step 1112.

In step 1111, the power interface reports no ground fault condition.

In step 1112, the microcontroller 640 calculates the magnitude of fault Rf 816 and the fault location voltage Vf 818. The Vf 818 indicates the location of the Rf 816 in the battery stack.

In step 1114, the microcontroller 640 reports the ground fault condition to the switch control 644 for controlling the switches 140a-c. As part of the step 1114, one of the LEDs 652 may light up to indicate “Fault.” As part of the step 1114, the power interface 602 may transmit the fault condition (Rf 816 and Vf 818) to the stack controller 502, grid battery controller 270, and/or external system 290.

In an embodiment, each of the steps of method 1100a is a distinct step. In another embodiment, although depicted as distinct steps in FIG. 11A, step 1102-1114 may not be distinct steps. In other embodiments, method 1100a may not have all of the above steps and/or may have other steps in addition to or instead of those listed above. The steps of method 1100a may be performed in another order.

FIG. 11B is a flowchart of an embodiment of a method 1100b of fault detection using fault pilot signals.

In step 1120, fault pilot signal is generated by the fault pilot signal generator (in 530) of the stack controller 150. As part of the step 1120, the fault pilot signal is embedded in the link bus 125 and stack bus 155.

In step 1124, the fault pilot signal suppressor (in 530) in the stack controller 502 may suppress fault pilot signal to indicate a fault condition (e.g., processor failure, loss of communication with the power interface 160 and/or cell interfaces 120a-n). As part of the step 1124, any of the fault pilot signal suppressor 712a-n in the cell interfaces 120a-n may suppress fault pilot signal to indicate fault (e.g., failure of AFE 410, loss of communication from the cell voltage taps 412 and/or temperature sensors 418). Optionally as part of the step 1124, the fault pilot signal suppressor 717 in the additional components may also suppress the fault pilot signal when fault occurs.

In step 1126, the fault pilot signal detector in the power interface 160 determines whether the fault pilot signal is detected. If yes (indicating there is no fault), the steps 1120-1126 may be repeated to continue the detection of fault pilot signals. If no, the absence of the fault pilot signal indicates a fault condition and the method 1100b then proceeds to step 1128 or step 1132.

In step 1128, the fault pilot signal detector 634 sends an output to the microprocessor 640 in the power interface 160. As part of the step 1128, the microprocessor 640 receives and analyzes the output. The output of absence of fault pilot signal indicates a fault condition.

In step 1130, the microcontroller 640 generates and sends control instructions to the switch control 644.

In step 1132, the fault pilot signal detector 634 receives instructions from external equipment 630. In an embodiment, the instructions may be used by the fault pilot signal detector 634 to decide whether the absence of the fault pilot signal should cause all controlled switches to be de-energized immediately.

In step 1134, the fault pilot signal detector 634 sends instructions to the switch control 644 directly. In at least one embodiment, steps 1132-1134 allow direct communication from the fault pilot signal detector 634 to the switch control 644 to control the switches 140a-c based on information from external equipment 630, in addition to the control mechanism through the microcontroller 640 (steps 1128-1130).

In step 1136, the switch control 644 controls the switch coils 650 of the switches 140a-c based on instructions received.

In an embodiment, each of the steps of method 1100B is a distinct step. In another embodiment, although depicted as distinct steps in FIG. 11B, step 1120-1136 may not be distinct steps. In other embodiments, method 1100B may not have all of the above steps and/or may have other steps in addition to or instead of those listed above. The steps of method 1100B may be performed in another order.

### Method of Assembling

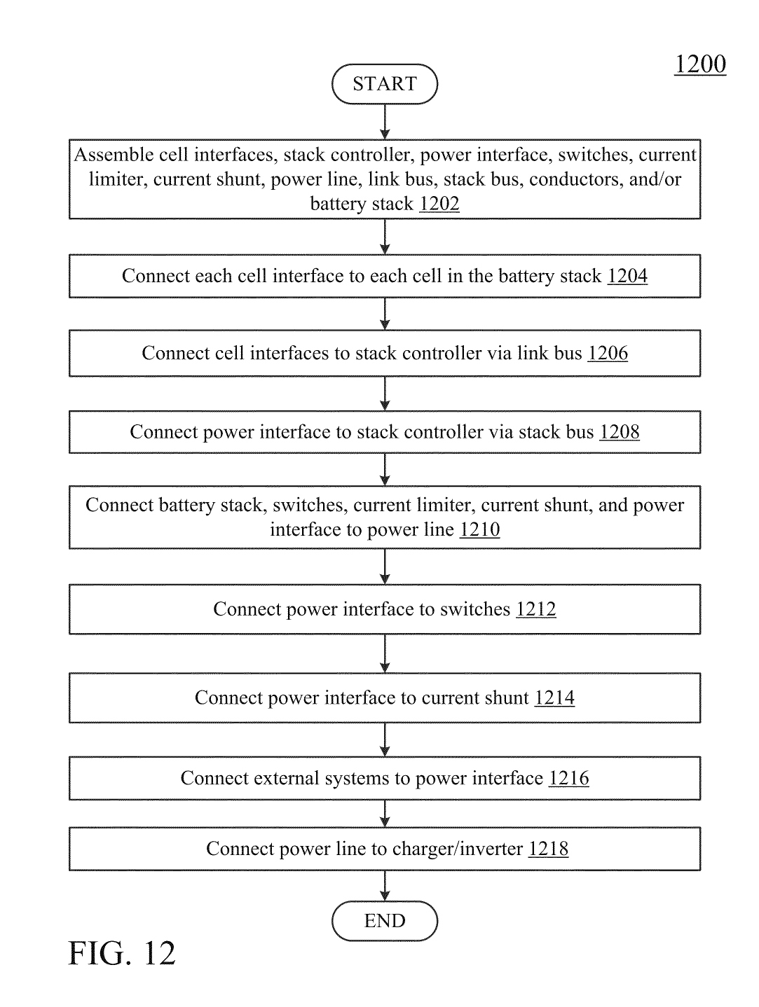

FIG. 12 is a flowchart of an embodiment of a method 1200 of assembling the battery management system 100.

In step 1202, the cell interfaces 120a-n, stack controller 150, power interface 160, switches140a-c, current limiter 175, current shunt 170, power line 130, link bus 125, stack bus 155, conductors165 and 167a-c, and/or battery stack 111 are assembled.

In step 1204, each of the cell interfaces 120a-n is connected to each of the battery cells 110a-n in the battery stack 111.

In step 1206, the cell interfaces 120a-n are connected in series via the link bus 125 to the stack controller 150.

In step 1208, the power interface 160 is connected to the stack controller 150 via the stack bus 155.

In step 1210, the battery stack 111 and current shunt are connected to the power line 130. As part of the step 1210, switches 140a and 140c are connected to the power line 130. As part of the step 1210, the current limiter 175 is connected to the switch 140b in series, and the current limiter 175 and switch 140b are connected to the switch 140a in parallel. As part of the step 1210, the power interface is connected to the power line 130 via the input conductor 165.

In step 1212, the power interface 160 is connected to the switches 140a-c via conductors 167a-c, respectively.

In step 1214, power interface is connected to the current shunt 170.

In step 1216, external systems are connected to the power interface 160 via Ethernet, CAN bus, USB, and/or Modbus.

In step 1218, the power line 130 is connected to the charger/inverter 135.

In an embodiment, each of the steps of method 1200 is a distinct step. In another embodiment, although depicted as distinct steps in FIG. 12, step 1202-1218 may not be distinct steps. In other embodiments, method 1200 may not have all of the above steps and/or may have other steps in addition to or instead of those listed above. The steps of method 1200 may be performed in another order.

### Alternatives and Extensions

Each embodiment disclosed herein may be used or otherwise combined with any of the other embodiments disclosed. Any element of any embodiment may be used in any embodiment.

Although the invention has been described with reference to specific embodiments, it will be understood by those skilled in the art that various changes may be made and equivalents may be substituted for elements thereof without departing from the true spirit and scope of the invention. In addition, modifications may be made without departing from the essential teachings of the invention.

1. A method, comprising:
monitoring, by at least one cell interface, a status of at least one battery cell, the at least one battery cell being connected in a circuit, the circuit delivering electrical current to and from the at least one battery cell;
sending, from the at least one cell interface to a controller, the status of the at least one battery cell, the controller being communicatively connected to the at least one cell interface and a power interface;
measuring, by the power interface, voltage and current in the circuit;
detecting, by the power interface, data indicative of whether a ground fault is present in the at least one battery cell;
sending, from the power interface to the controller, the voltage and current in the circuit and the data pertaining to the ground fault;
sending, from the controller to the power interface, instructions based on at least one of the status of the at least one battery cell, the voltage and current in the circuit, and the data pertaining to the ground fault; and
controlling, by the power interface, connection and disconnection of the circuit.

2. The method of claim 1, further comprising
controlling, by the power interface, at least one switch that is connected in the circuit, the at least one switch controlling connection and disconnection of the at least one battery cell from an electrical load.

3. The method of claim 1, wherein
the monitoring of the status of the at least one battery cell includes at least monitoring a voltage and a temperature of each of the at least one battery cell.

4. The method of claim 1, wherein
the at least one battery cell is connected in series in the circuit, forming a battery stack, the battery stack having a most positive end and a most negative end.

5. The method of claim 4, the detecting, by the power interface, the data indicative of whether a ground fault exists further including at least
measuring a first current from the most positive end of the battery stack to ground;
measuring a second current from the most negative end of the battery stack to the ground; and
determining the value of the first current and the second current, and determining whether a ground fault exists based on the value of the first current and the second current;
wherein if both of the first current and the second current are zero, no ground fault is detected in the battery stack; if at least one of the first current and the second current has a value other than zero, a ground fault is determined to exist in the battery stack.

6. The method of claim 5, further comprising
calculating the resistance of the ground fault;
calculating the voltage of the ground fault relative to the most negative end of the battery stack; and
determining a location of the ground fault based on the voltage of the ground fault relative to the most negative end of the battery stack.

7. The method of claim 6, further comprising
reporting the resistance and location of the detected ground fault by the power interface to the controller or an external system.

8. The method of claim 1, further comprising
generating, by the controller, a fault pilot signal that is propagated to the at least one cell interface and the power interface;
suppressing the fault pilot signal by at least one of the at least one cell interface and the power interface; and
detecting an absence of the fault pilot signal by the power interface, without reliance on software to make the detection, wherein the absence of the fault pilot signal indicates a problem.

9. The method of claim 8, wherein
the power interface provides direct current to the controller and the at least one cell interface, wherein the fault pilot signal propagates as an alternating current signal that is added to the direct current.

10. The method of claim 8, further comprising
indicating the status of the power interface by at least one light in the power interface, wherein at least one of the at least one light, when activated, indicates the problem.

11. The method of claim 8, the detecting the absence of the fault pilot signal by the power interface further comprising
detecting the absence of the fault pilot signal by a hardware-based signal detector;
sending a result of the detection to a microcontroller of the power interface, the microcontroller;
generating, by the microcontroller, control instructions in response to the absence of the fault pilot signal, the control instructions being sent to a circuit that controls at least one switch in the circuit; and
disconnecting, by the at least one switch, the circuit in response to the absence of the fault pilot signal.

12. The method of claim 8, further comprising
disconnecting directly the circuit in response to the detection of the absence of the fault pilot signal by the power interface, without the instructions from a microcontroller of the power interface.

13. The method of claim 12, further comprising
controlling, by an external system, whether the power interface is capable of directly disconnecting the circuit in response to the detection of the absence of the fault pilot signal, the external system being connected to the power interface.

14. The method of claim 1, further comprising
providing electrical power from the power interface to the controller and the at least one cell interface.

15. The method of claim 1, further comprising
controlling the controller by an external system that is communicatively connected to the controller.

16. The method of claim 1, wherein
the controller is one of a plurality of controllers, each controller controlling a battery stack that includes at least one battery cell connected in series, the plurality of controllers being connected in series, the method further including
controlling the plurality of controllers by a supervisory controller, the supervisory controller communicating with the plurality of controllers to send instructions to and retrieve data from the plurality of controllers, and
controlling, by an external system via the supervisory controller, power input to and output from the battery stacks that are controlled by the plurality of controllers, the external system being communicatively connected to the supervisory controller.

17. A method, comprising:
connecting at least one cell interface to at least one battery cell, the at least one battery cell being connected in series in a circuit, the circuit delivering electrical current to and from the at least one battery cell, wherein the at least one cell interface monitors status of the at least one battery cell;
communicatively connecting the at least one cell interface to a controller, wherein the at least one cell interface sends the status of the at least one battery cell to the controller;
communicatively connecting the controller to a power interface, wherein the power interface measures voltage and current in the circuit and sends the voltage and current to the controller, wherein the power interface detects data indicative of whether a ground fault exists;
wherein the controller sends to the power interface instructions based on at least one of the status of the at least one battery cell, the voltage and current in the circuit, and the data of the ground fault, wherein the power interface controls connecting and disconnecting the circuit.

18. A system, comprising:
at least one battery cell that is connected in a circuit, the circuit delivering electrical current to and from the at least one battery cell;
at least one cell interface that is connected to the at least one battery cell, wherein the at least one cell interface monitors status of the at least one battery cell and send the status to a controller;
a power interface that controls the connection and disconnection of the circuit, wherein the power interface measures voltage and current in the circuit and sends the voltage and current to the controller, wherein the power interface detects data indicative of whether a ground fault exists; and
the controller that is communicatively connected to the at least one cell interface and the power interface, the controller sends instructions to the power interface based on at least one of the status of the at least one battery cell, the voltage and current in the circuit, and data of the ground fault;
wherein the power interface controls the connecting and disconnecting the circuit.

19. The system of claim 18, further comprising
a battery stack that includes at least one battery cell connected in series, the battery stack having a most positive end and a most negative end, wherein the power interface measures a first current from the most positive end of the battery stack to ground and a second current from the most negative end of the battery stack to the ground, and determines whether a ground fault exists, wherein the power interface calculates a resistance and a location of the ground fault.

20. The system of claim 18, further comprising
a signal generator that is installed in the controller, the signal generator generating a fault pilot signal that is propagated to the at least one cell interface and the power interface;
at least one signal suppressor that is installed in at least one of the at least one cell interface and the controller, at least one of the at least one signal suppressor suppressing the fault pilot signal, if a fault exists; and
a signal detector that is installed in the power interface, the signal detector detecting an absence of the fault pilot signal.
